(19) United States
(12) Patent Application Publication
(10) Pub. No.: US 2026/0026351 A1
(43) Pub. Date: Jan. 22, 2026

(54) Multi-Channel Device Structure and Method Making the Same

(71) Applicant: Taiwan Semiconductor Manufacturing Company, Ltd., Hsin-Chu (TW)

(72) Inventors: Yun-Sheng LI, Hsinchu (TW); Chih Hsin YANG, Hsinchu County (TW); Mao-Nan WANG, Kaohsiung City (TW); Kuan-Hsun WANG, Hsinchu City (TW); Chih-Chieh CHANG, Hsinchu (TW); Yang-Hsin SHIH, Hsinchu County (TW)

(21) Appl. No.: 18/977,126

(22) Filed: Dec. 11, 2024

Related U.S. Application Data
(60) Provisional application No. 63/674,085, filed on Jul. 22, 2024.

(51) Int. Cl. H01L 23/58; H01L 21/78; H10D 30/01; H10D 30/43; H10D 30/67; H10D 62/10; H10D 64/01

(52) U.S. Cl. CPC H01L 23/585; H01L 21/78; H10D 30/014; H10D 30/43; H10D 30/6735; H10D 30/6757; H10D 62/121; H10D 64/017

(57) ABSTRACT

The present disclosure provides a semiconductor structure that includes a substrate having a circuit region and a seal ring region surrounding the circuit region, and a dicing lane surrounding the seal ring region, wherein the dicing lane includes a first dicing region and a second dicing region disposed on both sides of the first dicing region; first active regions formed in the circuit region; first gate stacks formed on the first active region in the circuit region, the first gate stacks including metal electrodes; second active regions formed in the first dicing region; dielectric structures formed on the second active regions in the first dicing region; and second gate stacks formed on an isolation feature in the second dicing region.

This application claims priority to U.S. Provisional Patent Application Ser. No. 63/674,085 filed Jul. 22, 2024, the entire disclosure of which is hereby incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing, and for these advancements to be realized, similar developments in IC processing and manufacturing are needed.

For example, etching may cause metal residue, which is a critical issue in some areas, such as through-semiconductor via region and plasma dicing lane due to tool capability. In another example, gate height variation leads to process issues, such as pattern density and processing uniformity. Therefore, although conventional IC devices have been generally adequate for their intended purposes, they are not satisfactory in every respect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a top plan view of the semiconductor structure 100 according to the present disclosure.

FIGS. 2A and 2F are top views of the window portion 116 of the semiconductor structure 100, respectively, constructed in accordance with some embodiment.

FIGS. 2B, 2C, 2D, and 2E are top views of the window portions 118, 120 and 122 of the semiconductor structure 100, respectively, constructed in accordance with some embodiment.

FIGS. 3A, 3B, 3C, 3D, 3E, and 3F are top views of the semiconductor structure 100 in the window 118 of FIG. 1 constructed in accordance with some embodiments.

FIGS. 4A, 4B, 4C, 4D, 4E and 4F are sectional views of the semiconductor structure in the window 120 of FIG. 1 cut along AA′ of FIG. 1 or FIG. 3B;

FIG. 5A is a sectional view of the semiconductor structure in the window 116 of FIG. 1 cut along CC′ of FIG. 1;

FIG. 5B is a sectional view of the semiconductor structure in the window 118 of FIG. 1 cut along BB′ of FIG. 1;

FIGS. 6A and 6D are sectional views of the semiconductor structure in the window 116 of FIG. 1 cut along DD′ of FIG. 1, constructed in accordance with some embodiments.

FIGS. 6B and 6C are sectional views of the semiconductor structure in the window 116 of FIG. 1 cut along CC′ of FIG. 1, constructed in accordance with some embodiments.

FIGS. 6E, 6G, 6H and 6I are sectional views of the semiconductor structure in the window 118 of FIG. 1 cut along AA′ of FIG. 1, constructed in accordance with some embodiments.

FIG. 6F is a sectional view of the semiconductor structure in the window 118 of FIG. 1 cut along BB′ of FIG. 1, constructed in accordance with some embodiments.

FIGS. 7, 8A, 8B, 8C and 8D are sectional views of the semiconductor structure in the window 118 of FIG. 1 cut along BB′ of FIG. 1, constructed in accordance with some embodiments.

FIGS. 9A, 9B, 9C and 9D are sectional views of the semiconductor structure in the window 120 of FIG. 1, constructed in accordance with some embodiments.

FIGS. 10A and 10B are flowcharts of a method making the semiconductor structure in FIG. 1, according to various aspects of the present disclosure.

FIGS. 11, 12, 13, 14 and 15 are sectional views of the semiconductor structure, constructed in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term encompasses numbers that are within certain variations (such as +/−30%, +/−20%, +/−10% or other variations) of the number described, in accordance with the knowledge of the skilled in the art in view of the specific technology disclosed herein, unless otherwise specified. For example, the term “about 5 nm” may encompass the dimension range from 4.5 nm to 5.5 nm, 4.0 nm to 5.0 nm, etc.

The disclosed device structure and the method making the same are related to an integrated circuit (IC) structure, such as 3D inter-chips (3DIC), system on chip (SoC), system on integrated chips (SoIC), other proper structure or a combination thereof. The disclosed device structure is related to an integrated circuit (IC) structure having multi-gate field effect transistors (FETs), especially, FETs formed on multiple channels vertically stacked, such as gate-all-around (GAA) FETs. Particularly, the disclosed device structure includes one or more plasma dicing (PD) structure.

Furthermore, the disclosed device structure includes one or more dicing region such as plasma dicing (PD) structure. The PD structure includes a PD lane; a seal ring structure; and a guard ring wall. The PD Lane is metal-free and includes dummy patterns. The PD lane includes a first region; and a second region surrounding the first region. The first PD region includes dummy active regions and dummy gates disposed on the dummy active regions; and the second PD region includes only dummy gates without active regions. In some embodiments, all dummy features in the PD lane 106 are metal-free. In some embodiments, at least a subset of dummy gates are metal gates.

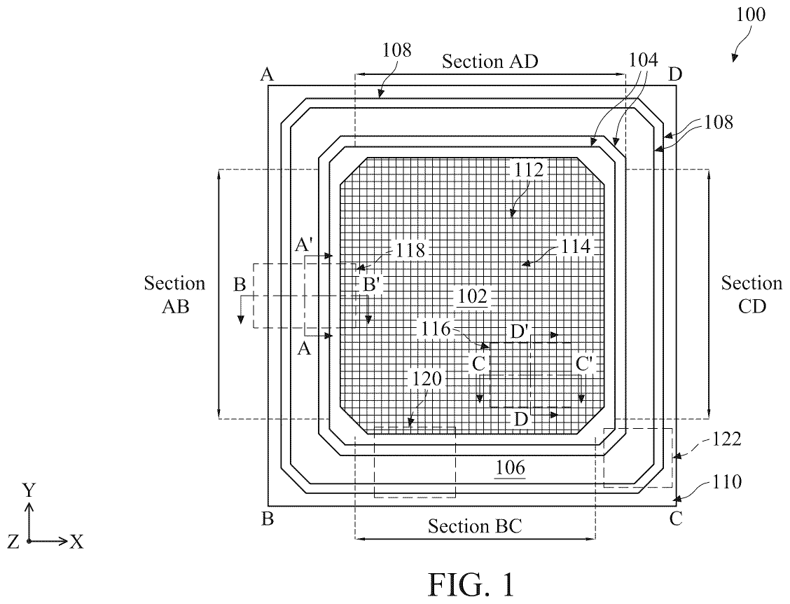

FIG. 1 is a top plan view of the semiconductor structure 100 according to the present disclosure. The semiconductor structure 100 (such as a manufactured wafer or a part thereof) includes a circuit region (or device region, IC die, chip area) 102; a seal ring region 104 that encloses the circuit region 102 from a top view; a dicing region 106 that encloses the seal ring region 104 from a top view; a guard ring wall 108 that encloses the dicing region 106 from a top view; and a boundary region 110 that encloses the boundary region 110 from a top view.

The circuit region 102 includes various devices formed on the substrate and an interconnect structure formed thereon to electrically connect devices into one or more integrated circuit (IC). In some embodiments, the circuit region 102 includes field-effect transistors (FETs), diodes, memory devices, passive devices, other devices, or a combination of. The FETs includes plane FETs, fin FETs, nano-sheet FETs, such as gate-all-around (GAA) FETs, complimentary FETs (CFTs) In the disclosed embodiment, the circuit region 102 includes active regions and metal gate electrodes designed in certain configuration.

The seal ring region 104 includes a seal-ring structure to provide protection to the integrated circuit in the circuit region from various environment damage, such as moisture and chemical. The seal-ring structure includes multiple layers vertically extending from the substrate, through an interconnect structure, and up to the passivation layer. The seal-ring structure may be formed simultaneously with the circuit features in circuit area (or chip area, device area, chip die) through various fabrication stages, such as in the front-end-of-line (FEOL) structures, the middle-end-of-line (MEOL) structures, and/or in back-end-of-line (BEOL) structures. As used herein, FEOL structures include structural features of transistors or other semiconductor devices fabricated on a semiconductor substrate; MEOL structures include source/drain contact vias or gate contact vias; and BEOL structure include interconnect structures and passivation structures over the interconnect structures. In the BEOL processes, conductive lines or vias are formed in multiple metal layers stacked over the semiconductor substrate to connect various features in the circuit region. Simultaneously, conductive rings and via rings are formed in the seal ring region of each metal layer. However, the conductive rings and the via rings in the seal ring region do not provide electrical functions for the semiconductor structure as the conductive lines and vias in the device region do. Instead, the conductive rings and via rings in the seal ring region encloses and protects the circuit area from moisture, mechanical stress, or other defect-generating mechanism. The differences in functionality cause the seal ring region to have properties different from the circuit region, such as pattern sizes and/or pattern density. The differences in properties may cause processing issues such as over etching in etching processes and/or dishing in chemical mechanical planarization (CMP) processes, especially in a region between the seal ring region and the circuit region.

The dicing region 106 is designed as a region so that a circuit substrate can be cut through to form a separate circuit die (chip) by any a suitable technology, such as mechanical saw dicing, laser dicing, dry etching dicing, blade dicing, plasma dicing, other dicing technology or a combination thereof. In the present embodiment, the plasma dicing is used, so the dicing region is also referred to as plasma dicing (PD) lane 106. During the plasma dicing process, various issues may be introduced into the semiconductor structure 100, such as metal residues, contaminations, other issues or a combination thereof. In the present disclosure, the PD lane 106 is designed with proper structure to eliminate various issues, such as metal residues introduced during etching. The PD lane 106 will be further described below in details.

The guard ring wall 108 is a region outside of the PD lane 106 with a structure similar to the seal ring structure in the seal ring region 104. The boundary region 110 is the region where various devices are formed for process control monitoring (PCM) during the IC fabrication process, therefore is also referred to as the PCM region 110. The guard ring wall 108 is also designed to protect the PCM region 110.

The semiconductor structure 100 includes a substrate, such as a semiconductor substrate, with a top surface spanning along x-direction and y-direction, various structures, such as IC devices, interconnect structure, and passivation structure, stacked along z-direction. The x-direction, y-direction, and z-direction constitute a Cartesian coordinate. In the disclosed embodiment, the semiconductor structure 100 includes proper shape, such as a square, rectangular or other proper shape. In furtherance of the embodiment, the semiconductor structure 100 includes four corners A, B, C and D, and four edges AB, BC, CD and DA.

The seal ring structure in the seal ring region 104 is disposed over a substrate and formed in multiple metal layers stacked thereover and along z-direction as discussed in detail below. The seal ring region 104 has a rectangular or substantially rectangular periphery fully surrounding the circuit region 102. The four corners A, B, C, and D of the rectangular periphery are replaced by four sloped corner lines that connects the adjacent sections AB, BC, CD, and AD of the seal ring region 104.

The semiconductor structure 100 includes various feature layers vertically extending from the substrate, through the interconnect structure, and up to the passivation layer, in both the device structure within the circuit region 102 and the seal ring structure within the seal ring region 104. The seal ring structure in the seal ring region 104 has a ring geometry designed for better protection to the circuit devices in the circuit region 102. Particularly, the seal ring structure in the seal ring region 104 also includes active regions, gate stacks and other features designed differently from those in the circuit region 102 for better protection of the circuit devices in the circuit region 102. For example, the active regions 112 in the circuit region 102 are longitudinally oriented along the x-direction while the active regions 112 in the seal ring region 104 are longitudinally oriented along the seal ring with a ring shape. In another example, the gate stacks 114 in the circuit region 102 are longitudinally oriented along the y-direction while the gate stacks 114 in the seal ring region 104 are longitudinally oriented along the seal ring with a ring shape. The guard ring walls 108 are configured similarly to the seal-ring structure in the seal ring region 104.

Furthermore, the PD lane 106 is configured differently from the circuit in the circuit region 102 and the seal-ring structure in the seal ring region 104, which will be further described below. A window portion 116 of the circuit region 102, and various window portions 118, 120 and 122 of the semiconductor structure 100 are further illustrated in following figures.

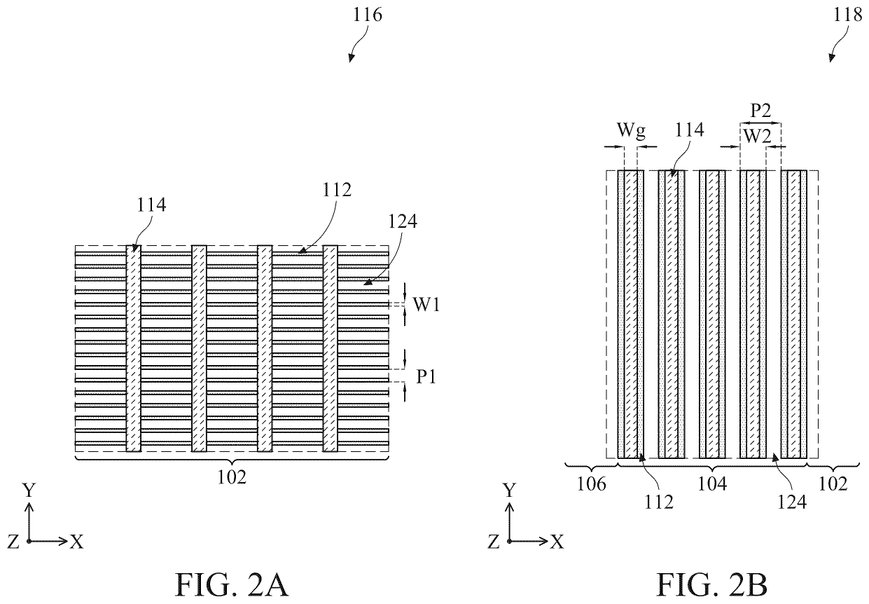

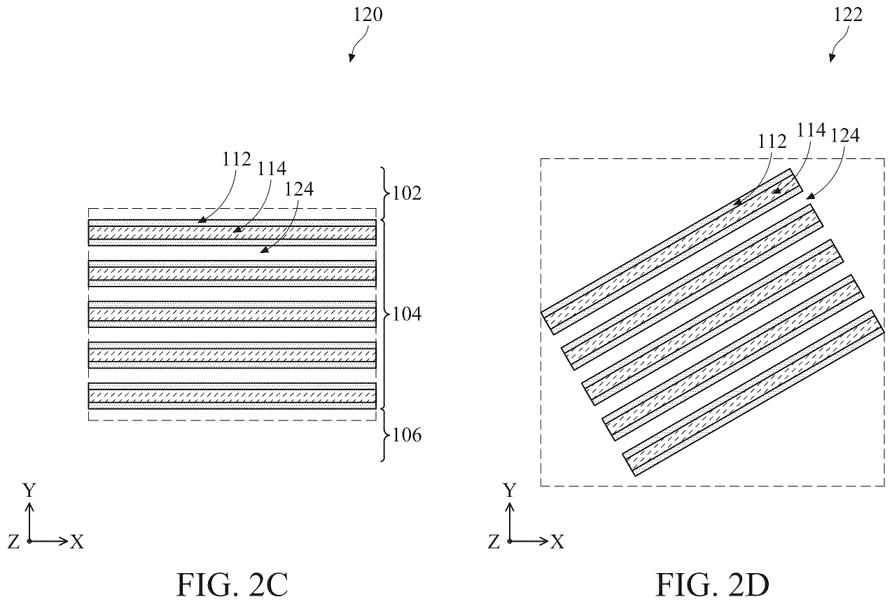

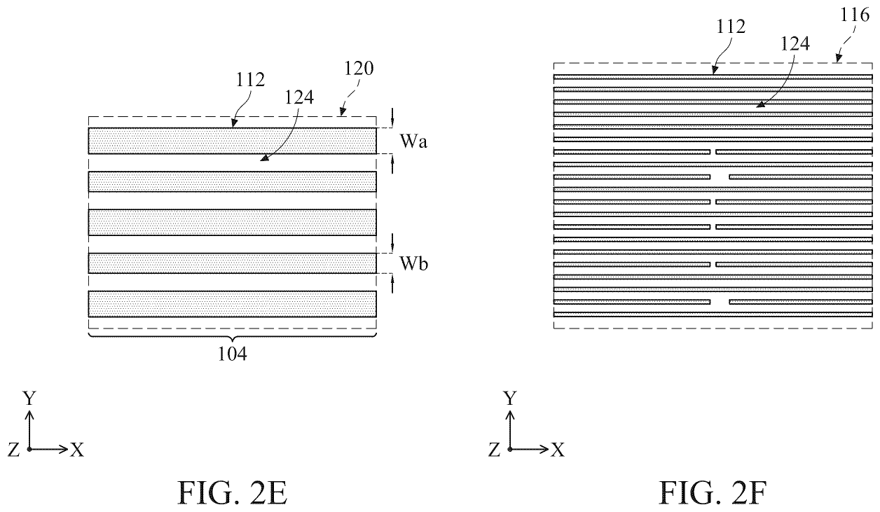

FIGS. 2A, 2B, 2C and 2D are top views of the window portions 116, 118, 120 and 122 of the semiconductor structure 100, respectively, constructed in accordance with some embodiments. Only active regions 112, gate stacks 114, and isolation features 124 are illustrated for simplicity. In the disclosed embodiments, the isolation features 124 are shallow trench isolation (STI) features. The active regions 112 are extruded from the substrate such that the top surface of the active regions is above the top surface of the isolation features 124. The active regions 112 include channel regions of transistors. A transistor can be FinFET, GAA FET, CFET, other suitable transistor, or a combination thereof. If it is GAA transistor, the active region will include multiple stacked nanostructures. The isolation features 124 are adjacent to each of the active regions so that various active regions are separated and isolated from each other. The gate stacks are conductive features in field effect transistors and are designed to couple to the channel(s) and cause electrical current to follow from source to drain. a gate stack includes a gate dielectric layer, a gate electrode disposed on the gate electric layer, and may further include gate spacers disposed on sidewalls of the gate electrode. The gate dielectric layer includes one or more dielectric material disposed on a semiconductor channel. For example, the gate dielectric layer includes a silicon oxide, high-k dielectric material, other suitable dielectric material or a combination thereof. The gate electrode includes one or more conductive material, such as copper, aluminum, cobalt, nickel, titanium, titanium nitride, tantalum, tantalum nitride, tungsten, other metal, metal alloy, or a combination thereof. The gate spacers include one or more dielectric material, such as silicon oxide, silicon nitride, silicon oxynitride, other suitable dielectric materials or a combination thereof.

As illustrated in FIG. 2A, the active regions 112 in the circuit region 102 are longitudinally oriented along the same direction (the x-direction) and the gate stacks 114 in the circuit region 102 are longitudinally oriented along the same direction (the y-direction).

The active regions 112 in the seal ring region 104 within the window portion 118 are longitudinally oriented in different directions so that they form ring shape to provide protection of the circuit devices in the circuit region 102. The segments of the active regions 112 adjacent sections BC and AD of the seal ring region 104 are longitudinally oriented along the X-direction as illustrated in FIG. 2C; the segments of the active regions 112 adjacent sections AB and CD of the seal ring region 104 are longitudinally oriented along the Y-direction as illustrated in FIG. 2B; and the segments of the active regions 112 in the corners are longitudinally oriented in titled angles (e.g., 45° from the X-direction) such that the those segments are connected to adjacent segments to form continuous rings as illustrated in FIG. 2D.

The active regions 112 in the circuit region 102 have a first width W₁ and the active regions 112 in the seal ring region 104 have a second width W₂ different from the first width W₁. Particularly, W₂ is substantially greater than W₁. In some embodiments, a ratio W₂/W₁ ranges between 5 and 15. In some embodiments, W₁ ranges between 0.02 μm and 0.08 μm; and W₂ ranges between 0.1 μm and 0.4 μm.

The active regions 112 in the circuit region 102 have a first pitch P₁ and the active regions 112 in the seal ring region 104 have a second pitch P₂ different from the first pitch P₁. Particularly, P₂ is substantially greater than P₁. In some embodiments, a ratio P₂/P₁ ranges between 2 and 6. In some embodiments, P₁ ranges between 0.05 μm and 0.2 μm; and P₂ ranges between 0.2 μm and 0.8 μm.

Furthermore, the dimensional parameters, such as W₂ and P₂, may vary, depending on factors of fabrication requirement (such as pattern density uniformity) and device performance. For example, those variations may be used to tune pattern density to provide optimal environment to and enhance the corresponding process (e.g., CMP or etching) and/or mechanical strength to reduce cracking issues, such as one illustrated in FIG. 2E, as a top view of the window portion 120 according to some embodiments. In this example, the width of the active regions 112 periodically vary from Wa to Wb, wherein Wb is less than Wa. For example, the ratio Wa/Wb ranges between 1.2 and 1.8. In various embodiments, the variation may be designed in random or periodic. The variation may be a combination of pitch variation and width variation. The width/pitch variation of ODs and gates in the seal-ring depend on process requirement (e.g., pattern density uniformity) to provide optimal environment for etching or CMP process.

The active regions 112 in the seal ring region 104 are further different from the active regions 112 in the circuit region 102 in term of continuity. The active regions 112 in the circuit region 102 are not continuous and are segmented, depending on individual circuit and design layout, as illustrated in FIG. 2F. However, the active regions 112 in the seal ring region 104 are continuously extending around the circuit region. The active regions 112 in the seal ring region 104 includes multiple active regions 112, each is continuously extending into a ring shape, such as extending from AB section, continuously extending to the corner B, continuously extending to BC section, continuously extending to the corner C, continuously extending to CD section, continuously extending to the corner D, and continuously extending to DA section, and continuously extending back to the corner A. It is noted that the number of active regions 112 in the seal ring region 104 is not limited to any particular number and may include any proper number such as 4 to 8, depending on individual circuit and design.

Furthermore, the gate stacks 114 in the circuit region 102 and the seal ring regions 104 are configured differently. In the disclosed embodiment, the gate stacks 114 in the circuit region 102 are longitudinally oriented in the Y-direction, which is orthogonal to the orientation (X-direction) of the active region 112 in the circuit region 102. In contrary, the gate stacks 114 in the seal ring region 104 are longitudinally oriented in parallel with the orientation (Y-direction) of the active region 112 in the seal ring region 104. Furthermore, the gate stacks 114 are completely landing on the respective active regions 112. For example, the gate stacks 114 are landing on the center of the active regions 112 with margins on both sides, such as equal margin on both sides. In this case, the width Wg of the gate stacks 114 is less than the width W2 of the active regions 112. In some embodiments, the ratio W2/Wg ranges between 1.5 and 2. Such configuration of the gate stacks 114 and active regions 118 in the seal ring region 104 make the sealing structure more robust. The continuity from the active region 112 to the gate stack 114 provides better sealing effect. In the present embodiments, the gate stacks 114 are simultaneously formed with same compositions, such as by gate replacement. For example, the gate stacks 114 include a gate dielectric layer (such as an interfacial layer and a high-k dielectric material layer) and a gate electrode (such as metal materials that further include a work function metal layer and a fill metal layer).

The active regions 112 and gate stacks 114 in the guard ring wall region 108 may have similar structure to that of the seal-ring structure in the seal ring region 104 in terms of orientation and continuity. For example, the active regions 112 in the guard ring wall region are oriented to form multiple continuous rings to surround the PD lane 106.

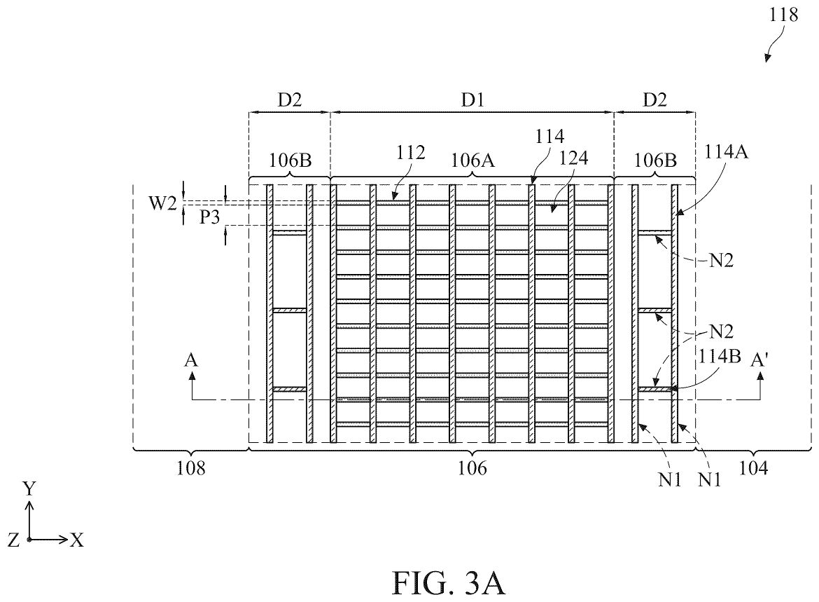

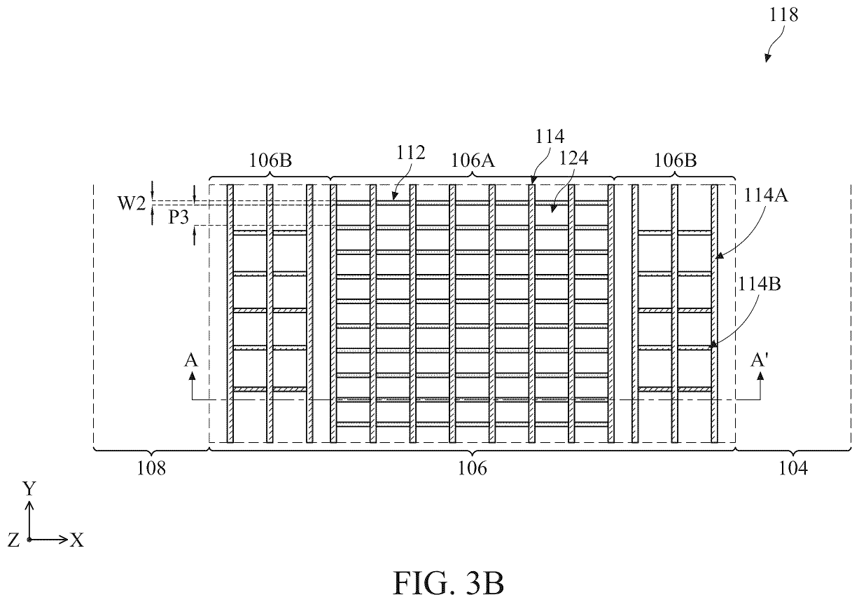

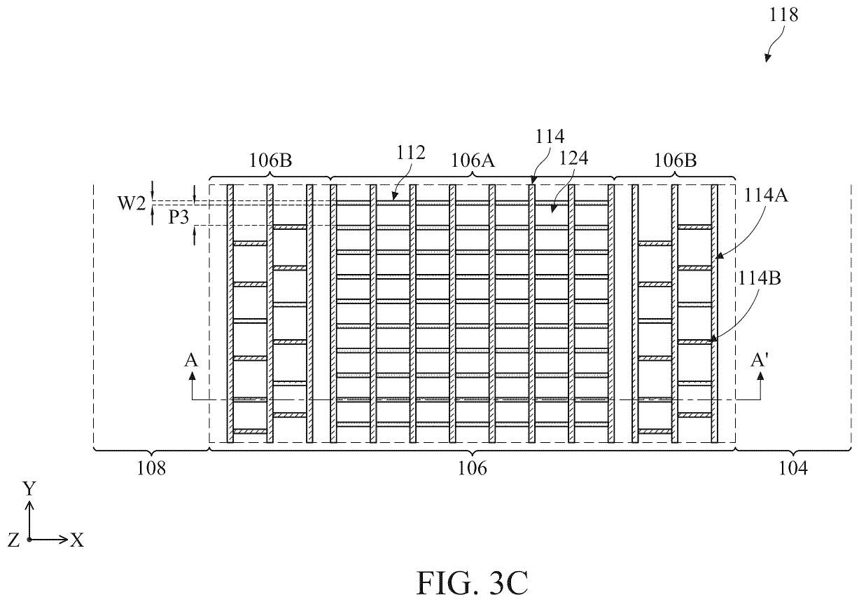

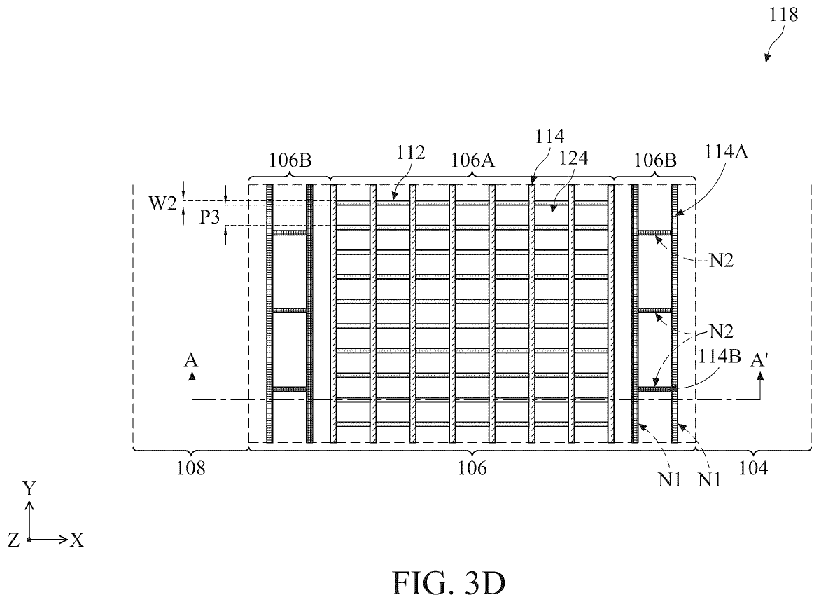

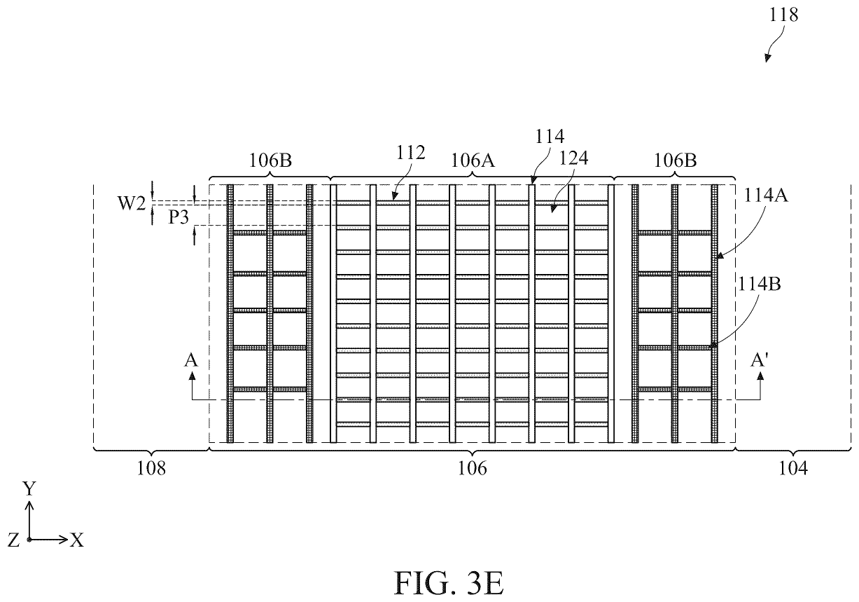

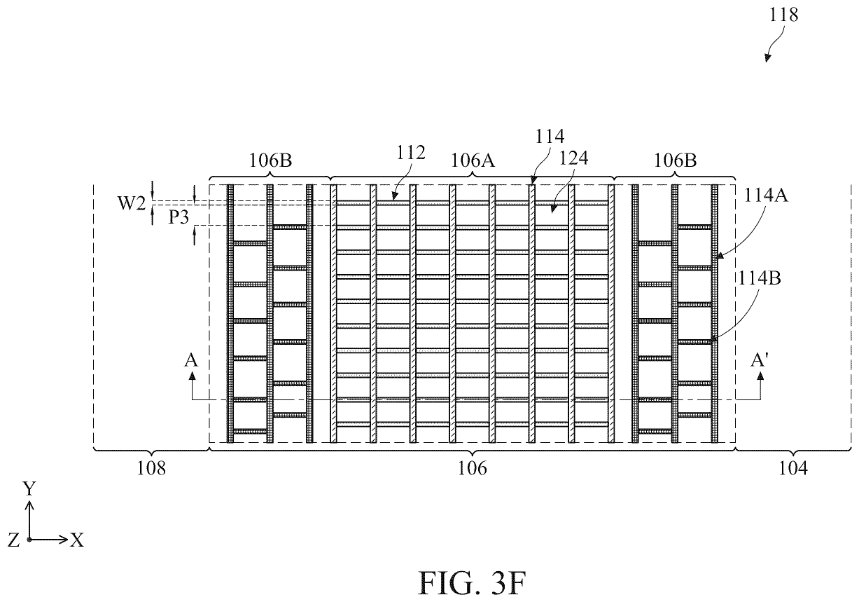

With further reference to following figures, the semiconductor structure 100, particularly the structure in PD lane 106 is further described below in detail. The PD lane 106 in the window portion 118 is first described below with refence to FIGS. 3A through 3F according to various embodiments.

Referring to FIG. 3A, the PD lane 106 is interposed between the seal ring region 104 and the guard ring wall region 108. The active regions 112 and the gate stacks 114 in the adjacent seal ring region 104 and the guard ring wall region 108 are described above and not repeated here.

The gate structure and active regions in the PD lane 106 are dummy features and designed different from those in the circuit region 102 those in the seal ring region 104 and those in the guard ring wall 108. Especially, the gate stacks in the PD lane 106 are different in orientation and composition from those in the circuit region 102. In some embodiments, the gate stacks in the PD lane 106 are dielectric features, also being referred to as dielectric gate stacks or simply dielectric structures. In this case, the gate stack, as a whole, is a dielectric feature, and does not include gate electrode or any conductive component. Even though, the dielectric gate stack is still referred to as gate stack 114 but it is understood that it is different from a functional gate stack that either includes a metal gate electrode or a polysilicon gate electrode. In some figures below, those dielectric gate stacks are also referred with different numeral, such as a numeral 242.

In the PD lane 106, the gate stacks 114 in the PD lane 106 within the window portion 118 are longitudinally oriented in the same direction (y-direction) to the gate stacks 114 in the circuit region 102. However, the active regions 112 and the gate stacks 114 in the PD lane 106 are configured differently.

The PD lane 106 includes two regions: a central region 106A and side regions 106B configured on both sides of the central region 106A. In the disclosed embodiment, the central region 106A is the dicing region to be cut through, such as by plasma dicing. The side regions 106B are buffer regions between the dicing region and the seal ring region 104 or between the dicing region and the guard ring wall region 108. The buffer regions are not to be cut but to provide buffer. The central region 106A spans a dimension D1 along the x-direction and the side region 106B spans a dimension D2 along the x-direction. The PD lane 106 spans a dimension D along the x-direction, in which D=D1+2*D2. In some embodiments, D ranges between 2 μm and 10 μm; and D1 ranges between 0.5 μm and 2.5 μm.

In the following embodiments, the dummy features in the central region 106A and the side regions 106B are designed differently.

In the central region 106A, the active regions 112 are longitudinally oriented in the same direction (x-direction). In the disclosed embodiment, the active regions 112 are continuously extending along x-direction to edges of the central region 106A. The gate stacks 114 are longitudinally oriented in the same direction (y-direction). In the disclosed embodiment, the gate stacks 114 are continuously extending along y-direction to edges of the central region 106A. In the disclosed embodiment, two gate stacks 114 are configured on both ends of the active regions 112. In furtherance of the embodiment, the active regions 112 in the central region 106A are periodically configured along y-direction, and the gate stacks 114 in the central region 106A are periodically configured along x-direction.

In some embodiments, the active regions 112 in the central region 106A have a third width W₃ different from the first width W₁ and a third spacing P₃ different from the first P₁. Particularly, W₃ is substantially greater than W₁. In some embodiments, a ratio W₃/W₁ ranges between 2 and 4. In some embodiments, W₃ ranges between 0.04 μm and 0.15 μm.

The side regions 106B is free of any active region 112 but include gate stacks 114 configured differently. Especially, the gate stacks 114 include a first subset of gate stacks 114A longitudinally oriented along y-direction and a second subset of gate stacks 114B longitudinally oriented along x-direction. In the disclosed embodiment, the first subset of the gate stacks 114A are similar to the gate stacks 114 in the central region 106A in terms of orientation and dimensions. The second subset of the gate stacks 114B span a length less than the length of the first subset of the gate stacks 114A according to the disclosed embodiment. The first subset of the gate stacks 114A and the second subset of the gate stacks 114B are connected to each other as illustrated in FIG. 3A. The number N1 of the first subset of gate stacks 114A and the number N2 of the second subset of gate stacks 114B on each side region 106B can be any proper integers, such as N1=2 and N2=3, depending on individual circuits. In various examples, each of N1 and N2 ranges between 2 and 10.

Especially, the gate stacks 114 in the PD lane 106 are further different from the gate stacks 114 in the circuit region 102 in term of composition, dimensions and formation. The gate stacks 114 in the PD lane 106 are dielectric features and include one or more dielectric material according to some embodiments. In the disclosed embodiment, the gate stacks 114 in the PD lane 106 are all made of one or more dielectric material. In furtherance of the embodiments, the gate stacks 114 in the PD lane 106 are made of silicon nitride (SiN). Furthermore, the gate stacks 114 in the PD lane 106 are vertically extending along z-direction with a dimension greater than that of the gate stacks 114 in the circuit region 102. In addition to that, the gate stacks 114 in the PD lane 106 are formed by different methods. In some embodiments, the gate stacks 114 in the PD lane 106 are formed by a procedure that includes forming dummy gate stacks and replacing the dummy gate stacks with a dielectric material. In some embodiments, the gate stacks 114 in the PD lane 106 are formed with gate cut features by a gate cut procedure. A gate cut process includes a procedure to pattern the gate stacks using lithography process and etching to cut long gate stacks to shorter segments, resulting in trenches; and filling one or more dielectric material into the trenches to form the gate cut features, and simultaneously form gate stacks 114 in the PD lane 106 in the present case.

FIG. 3B provides another embodiment of the dummy structure in PD lane 106. FIG. 3B is similar to FIG. 3A. Similar descriptions are not repeated herein for simplicity. However, the gate stacks 114 in the side regions 106B are configured differently. In the disclosed embodiments, N2 is greater N1, and N1=3 and N2=5. As described above, N1 and N2 can be any proper integers. Furthermore, the second subset of gate stacks 114B interposed between different pairs of the gate stacks 114A are respectively aligned along x direction.

FIG. 3C provides yet another embodiment of the dummy structure in PD lane 106. FIG. 3B is similar to FIG. 3A. Similar descriptions are not repeated herein for simplicity. However, the gate stacks 114 in the side regions 106B are configured differently. In the disclosed embodiments, N2 is greater N1, and N1=3 and N2=6. As described above, N1 and N2 can be any proper integers. Furthermore, the second subset of gate stacks 114B interposed between different pairs of the gate stacks 114A are respectively offset along x direction or are configured in a staggered mode.

As described above, during various etching processes, metal residues may be introduced into the PD lane 106. This will cause concerns to the plasma dicing, such as dicing effectiveness, dicing uniformity, chipping and cracking. As the PD lane 106 are designed with dielectric gate stacks and are free of any metal, the etching processes will not introduce metal residues in the PD lane 106. Those issues are eliminated and substantially reduced.

In some embodiments, the gate stacks 114B in the side regions 106B are metal gate stacks similar to the gate stacks 114 within the circuit region 102 in term of composition, such as those illustrated in FIGS. 3D through 3F.

The dummy structure in the PD lane 106 in FIG. 3D is similar to that of FIG. 3A. However, the gate stacks 114B in the side regions 106B are metal gate stacks while the gate stacks 114A in the central regions 106A are dielectric features, such as dielectric features of silicon nitride. In the disclosed embodiment, a gate stack 114B in the side regions 106B includes a gate dielectric layer of one or more dielectric material, and a gate electrode of one or more conductive material (such as metal, metal alloy or combinations thereof) disposed on the gate dielectric layer, and gate spacers disposed on sidewalls of the gate electrode, those gate stacks being referred to as metal gate stacks. In the present embodiment, the gate stacks 114B in the side regions 106B are simultaneously formed with the gate stacks 114 in the circuit region 102. For example, both are formed by a procedure that includes forming dummy gate stacks (such as polysilicon gate stacks) and replacing the dummy gate stacks with metal gate stacks. However, the gate stacks 114B in the side regions 106B are different from the gate stacks 114 in the circuit region 102 in terms of dimensions and configuration.

As described above, in the PD lane, the central region 106A and the side regions 106B experience differently, such as experiencing differently during etching and plasma dicing, and therefore are designed differently to reduce dicing issues (such as metal residues during plasma dicing) and achieve/maintain other processing performance (such as pattern density and chemical mechanical polishing (CMP) uniformity) as well. This is because the metal residues, if any, are only present in the side regions 106B and away from the central region 106A, therefore, the central region 10A as the dicing region is free of any metal, therefore eliminating the issues associated with metal residues.

The dummy structure in the PD lane 106 in FIG. 3E is similar to that of FIG. 3B. However, the gate stacks 114B in the side regions 106B are metal gate stacks while the gate stacks 114A in the central regions 106A are dielectric features, such as dielectric features of silicon nitride.

The dummy structure in the PD lane 106 in FIG. 3F is similar to that of FIG. 3C. However, the gate stacks 114B in the side regions 106B are metal gate stacks while the gate stacks 114A in the central regions 106A are dielectric features, such as dielectric features of silicon nitride.

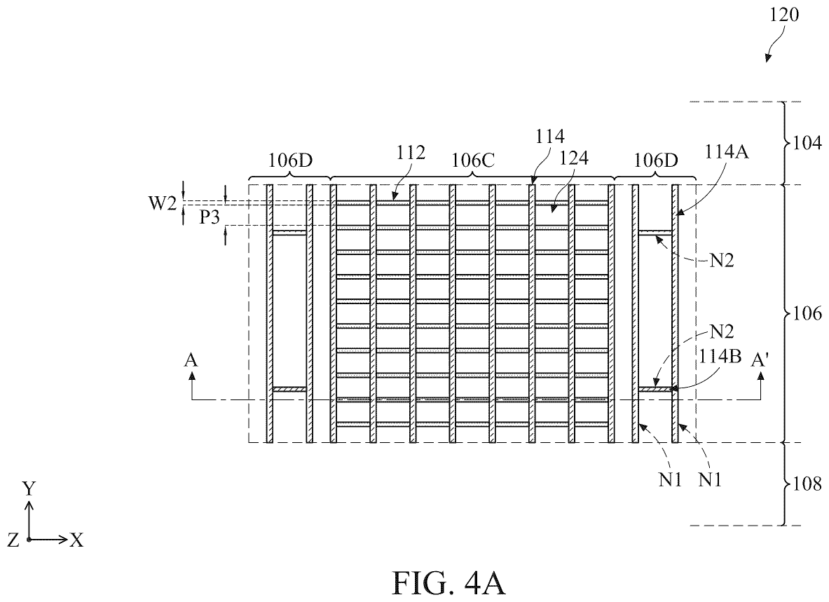

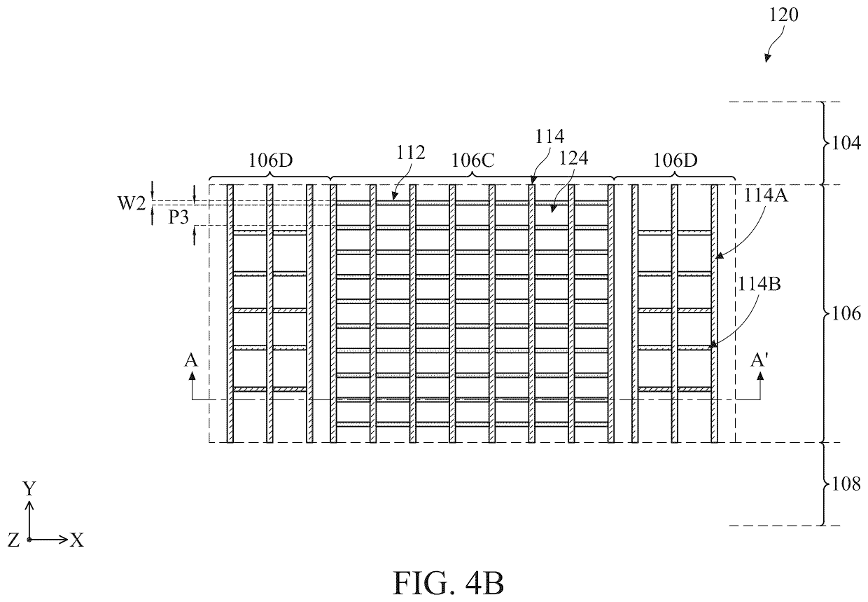

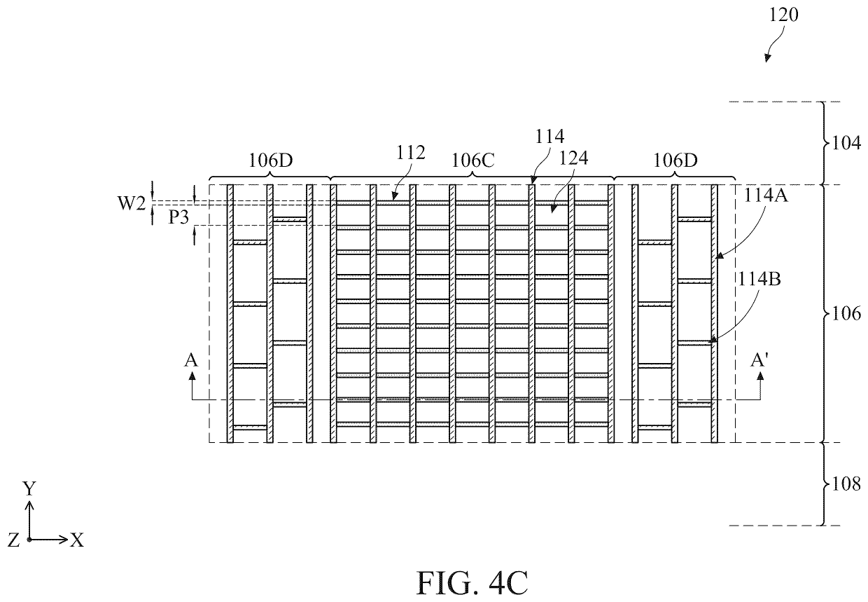

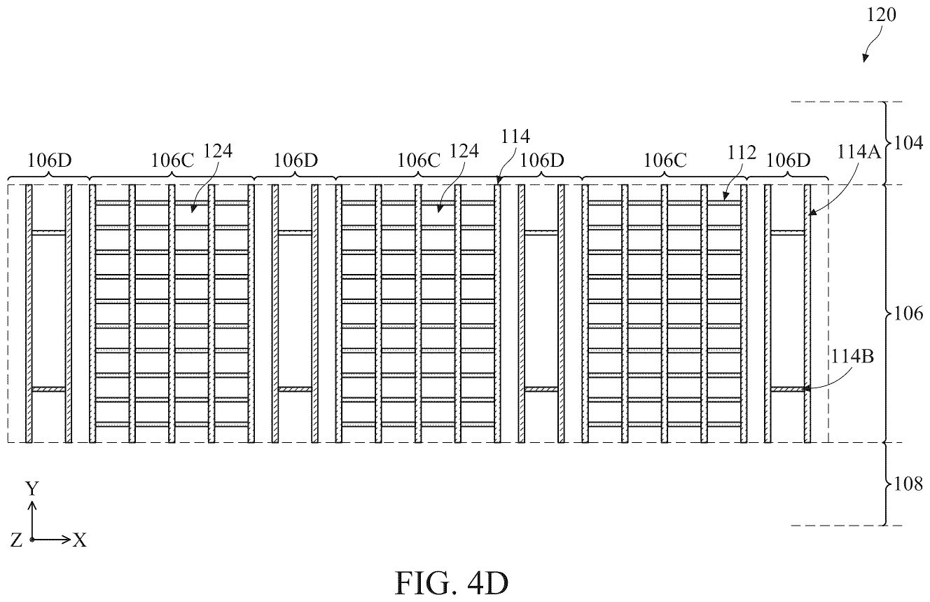

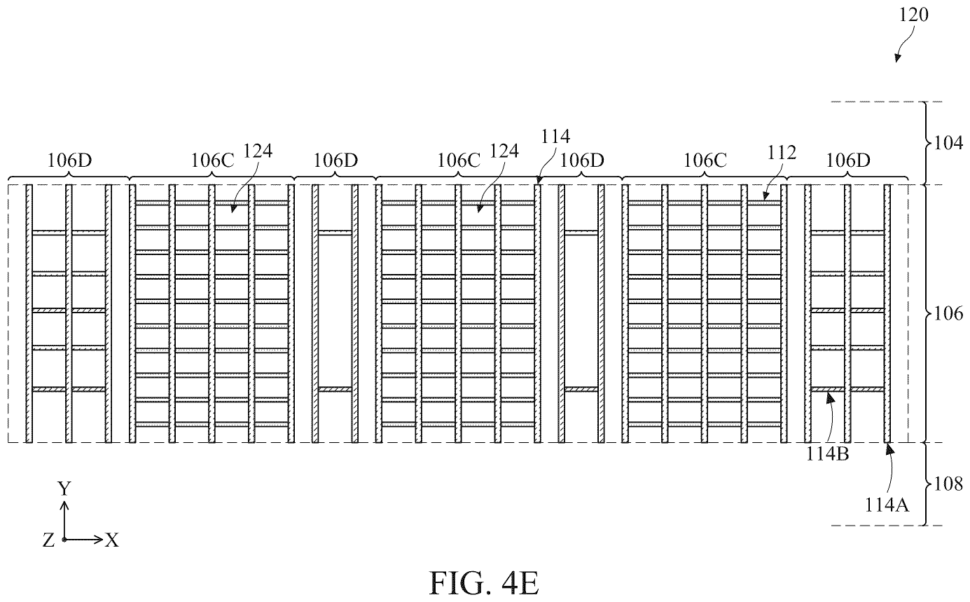

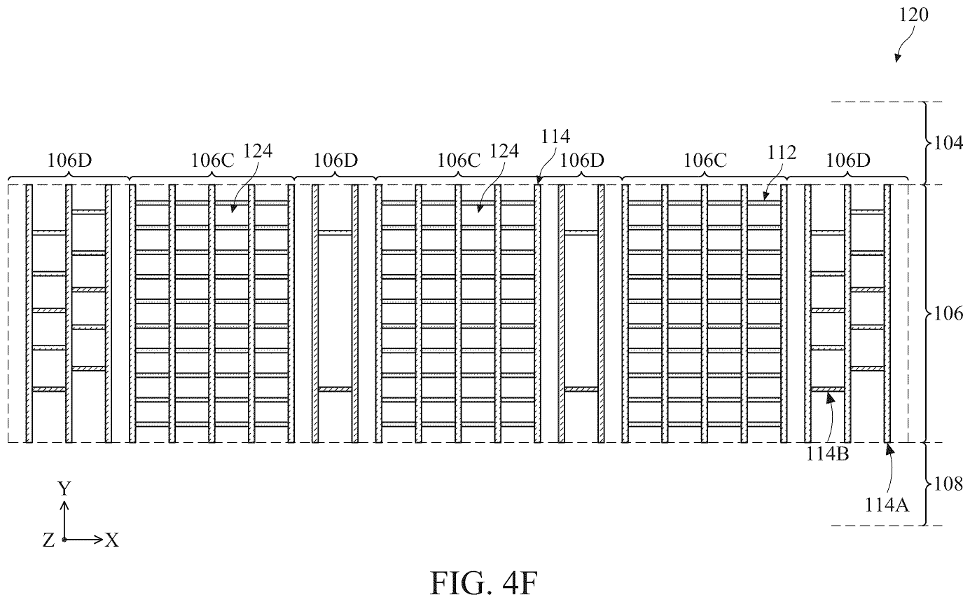

Now the PD lane 106 in the window portion 120 is described below with refence to FIGS. 4A through 4F according to various embodiments. In this case, the seal ring region 104 and the guard ring wall region 108 are disposed on both sides of the PD lane 106 along the y-direction. Note that the dummy features in the PD lane 106 in the window portion 120 are different from the dummy features in the PD lane 106 in the window portion 118 in terms of the configuration and composition. Especially, all gate stacks 114 in the PD lane 106 within the window portion 120 are free of metal and are dielectric features, such as dielectric features of SiN. This is because the plasma dicing process will cut through all subregions of the PD lane 106. The metal free gate stacks 114 in the PD lane 106 within the window portion 120 can effectively eliminate the metal residues and enhance the plasma dicing performance.

Referring to FIG. 4A, the PD lane 106 is interposed between the seal ring region 104 and the guard ring wall region 108 along x-direction. The active regions 112 and the gate stacks 114 in the adjacent seal ring region 104 and the guard ring wall region 108 are described above and not repeated here.

The gate stacks 114 in the PD lane 106 within the window portion 118 are longitudinally oriented in the same direction (y-direction) to the gate stacks 114 in the circuit region 102. However, the active regions 112 and the gate stacks 114 in the PD lane 106 are configured differently.

The PD lane 106 includes two regions: a first region 106C and second regions 106D configured on both sides of the first region 106C. In the following embodiments, the dummy features in the first region 106C and the second regions 106D are designed differently. The dummy features in the PD lane 106 are similar to the dummy features in the PD lane within the window portion 118 but the central region 106A is replaced by the first region 106C and the side regions 106B are replaced by the second regions 106D. Similar descriptions are not repeated herein for simplicity.

In the first region 106C, the active regions 112 are longitudinally oriented in the same direction (x-direction). In the disclosed embodiment, the active regions 112 are continuously extending along x-direction to edges of the first region 106C. The gate stacks 114 are longitudinally oriented in the same direction (y-direction). In the disclosed embodiment, the gate stacks 114 are continuously extending along y-direction to edges of the first region 106C. In the disclosed embodiment, two gate stacks 114 are configured on both ends of the active regions 112. In furtherance of the embodiment, the active regions 112 in the first region 106C are periodically configured along y-direction, and the gate stacks 114 in the first region 106C are periodically configured along x-direction.

In some embodiments, the active regions 112 in the first region 106C have a third width W₃ different from the first width W₁ and a third spacing P₃ different from the first P₁. Particularly, W₃ is substantially greater than W₁. In some embodiments, a ratio W₃/W₁ ranges between 2 and 4. In some embodiments, W₃ ranges between 0.04 μm and 0.15 μm.

The second regions 106D is free of any active region 112 but include gate stacks 114 configured differently. Especially, the gate stacks 114 include a first subset of gate stacks 114A longitudinally oriented along y-direction and a second subset of gate stacks 114B longitudinally oriented along x-direction. In the disclosed embodiment, the first subset of the gate stacks 114A are similar to the gate stacks 114 in the first region 106C in terms of orientation and dimensions. The second subset of the gate stacks 114B span a length less than the length of the first subset of the gate stacks 114A according to the disclosed embodiment. The first subset of the gate stacks 114A and the second subset of the gate stacks 114B are connected to each other as illustrated in FIG. 4A. The number N1 of the first subset of gate stacks 114A and the number N2 of the second subset of gate stacks 114B on each second region 106D can be any proper integers, such as N1=2 and N2=2, depending on individual circuits. In various examples, each of N1 and N2 ranges between 1 and 5.

Especially, the gate stacks 114 in the PD lane 106 are further different from the gate stacks 114 in the circuit region 102 in term of composition, dimensions and formation. The gate stacks 114 in the PD lane 106 are dielectric features and include one or more dielectric material according to some embodiments. In the disclosed embodiment, the gate stacks 114 in the PD lane 106 are all made of one or more dielectric material. In furtherance of the embodiments, the gate stacks 114 in the PD lane 106 are made of silicon nitride (SiN). In some embodiments, the gate stacks 114 in the PD lane 106 are made of silicon nitride (SiN), silicon oxynitride, silicon oxide, other suitable dielectric material, or a combination thereof. Furthermore, the gate stacks 114 in the PD lane 106 are vertically extending along z-direction with a dimension greater than that of the gate stacks 114 in the circuit region 102. In addition to that, the gate stacks 114 in the PD lane 106 are formed by different methods. In some embodiments, the gate stacks 114 in the PD lane 106 are formed by a procedure that includes forming dummy gate stacks and replacing the dummy gate stacks with a dielectric material. In some embodiments, the gate stacks 114 in the PD lane 106 are formed with gate cut features by a gate cut procedure. A gate cut process includes a procedure to pattern the gate stacks using lithography process and etching to cut long gate stacks to shorter segments, resulting in trenches; and filling one or more dielectric material into the trenches to form the gate cut features, and simultaneously form gate stacks 114 in the PD lane 106 in the present case.

FIG. 4B provides another embodiment of the dummy structure in PD lane 106. FIG. 4B is similar to FIG. 4A. Similar descriptions are not repeated herein for simplicity. However, the gate stacks 114 in the second regions 106D are configured differently. In the disclosed embodiments, N2 is greater N1, and N1=3 and N2=4. As described above, N1 and N2 can be any proper integers. In the disclosed embodiment, the second subset of gate stacks 114B interposed between different pairs of the gate stacks 114A are respectively aligned along x direction. Furthermore, the second subset of gate stacks 114B on the second region 106D on the left side and the second region 106D on the right side are respectively aligned along x direction.

FIG. 4C provides yet another embodiment of the dummy structure in PD lane 106. FIG. 4C is similar to FIG. 3C. Similar descriptions are not repeated herein for simplicity. However, the gate stacks 114 in the second regions 106D are configured differently. In the disclosed embodiments, N2 is greater N1, and N1=3 and N2=4. As described above, N1 and N2 can be any proper integers. Furthermore, the second subset of gate stacks 114B interposed between different pairs of the gate stacks 114A are respectively offset along x direction or are configured in a staggered mode.

As described above, during various etching processes, metal residues may be introduced into the PD lane 106. This will cause concerns to the plasma dicing, such as dicing effectiveness, dicing uniformity, chipping and cracking. In the PD lane 106, all gate stacks 114, including 114A and 114B are designed with dielectric gate stacks and are free of any metal.

FIG. 4D provides yet another embodiment of the dummy structure in PD lane 106. The dummy structure in the PD lane 106 in FIG. 4D is similar to that of FIG. 4A. However, the PD lane 106 includes multiple first regions 106C and second regions 106D alternatively disposed along x-direction. Each of the first regions 106C is similar to the first region 106C in FIG. 4A. Each of the second regions 106D is similar to the second region 106D in FIG. 4A. In the present embodiments, the dummy structure in the PD lane 106 within the window portion 120 includes three of the first regions 106C and four of the second regions 106D. However, those numbers can be different, depending on the side of the window portion 120 and individual design. In furtherance of the embodiment, all of the first regions 106C are identical and all of the second regions 106D are identical.

Particularly, the active regions 112 are only formed in the first regions 106C and the gate stacks 114 in the second regions 106D include a first subset 114A longitudinally oriented along y-direction a second subset 114B longitudinally oriented along x-direction.

Note that the gate stacks 114, including the gate stacks 114A and 114B, in the second regions 106D are all metal free and are dielectric features, being different from the gate stacks 114 in the side regions 106B within the window portion 118.

The dummy structure in the PD lane 106 in FIG. 4E is similar to that of FIG. 4D. The PD lane 106 includes multiple first regions 106C and second regions 106D alternatively disposed along x-direction. Each of the first regions 106C is similar to the first region 106C in FIG. 4D and each of the second regions 106D is similar to the second region 106D in FIG. 4D. However, the second regions 106D are not identical and may have different numbers of gate stacks 114A and different dimensions. In the present embodiment, the second regions 106D includes a first subset having a first dimension along x-direction and a second subset having a second dimension along x direction. The second dimension is greater than the first dimension.

The dummy structure in the PD lane 106 in FIG. 4F is similar to that of FIG. 3E. The second regions 106D are not identical and may have different numbers of gate stacks 114A and different dimensions. In the present embodiment, the second regions 106D includes a first subset having a first dimension along x-direction and a second subset having a second dimension along x direction. The second dimension is greater than the first dimension.

However, the gate stacks 114B in the second subset of the second regions 106D are configured to be off set and in a staggered mode. the gate stacks 114B in the first subset of the second regions 106D are configured to be aligned along x-direction.

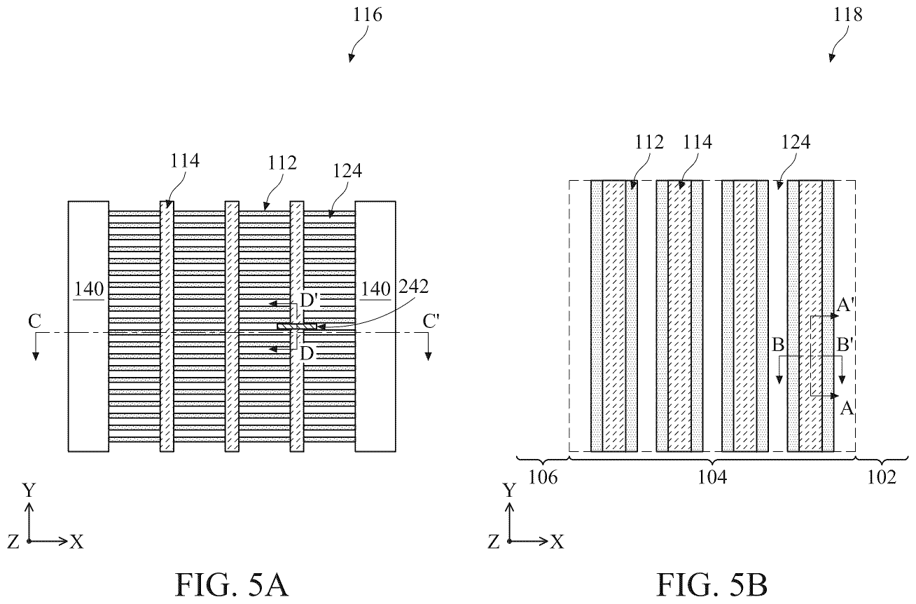

FIG. 5A is a top view of the semiconductor structure 100 in the window 116 of FIG. 1; and FIG. 5B is a top view of the semiconductor structure 100 in the window 118 of FIG. 1 constructed in accordance with some embodiments. FIG. 5A is similar to FIG. 2A, and FIG. 5B is similar to FIG. 2B. Furthermore, various cut features, such as active region cut features 140 and gate cut features 142, are also formed and illustrated. The active region cut features 140 are dielectric features formed to separate long active regions 112 during double patterning process or multiple patterning process. For examples, the active regions are first formed in the first patterning process and the second patterning process cut the long active regions into short active regions according to design layout. In this case, the cut process includes forming a patterned resist layer by lithography process, etching to form trenches that cut the active regions, depositing dielectric material to fill the trenches, and may further apply a CMP process to remove the excessive dielectric material. Similarly, the gate cut features have similar function to the gate stacks and formed by the similar method.

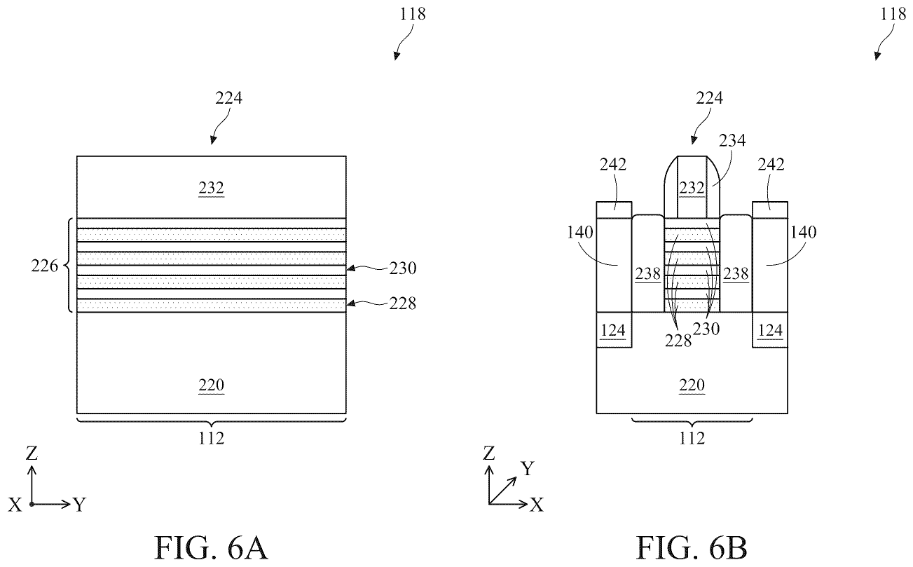

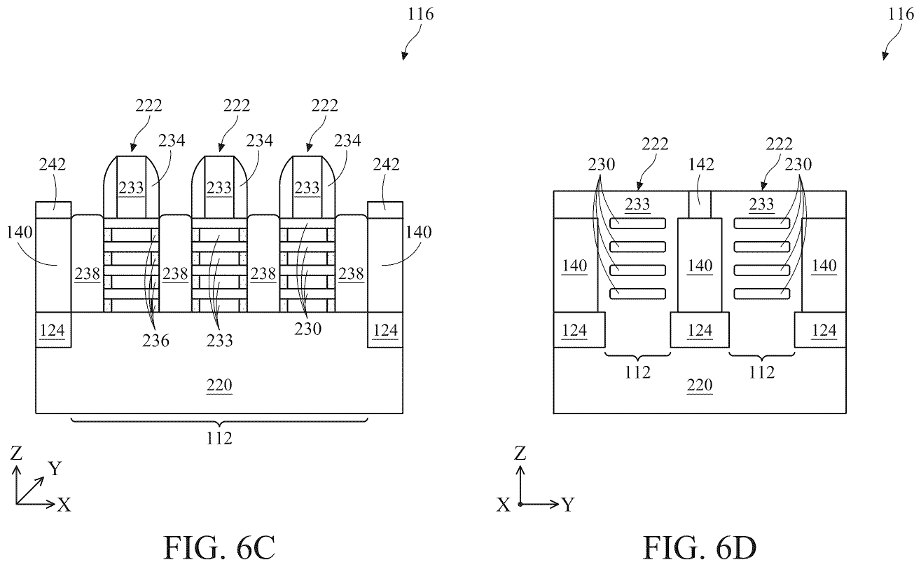

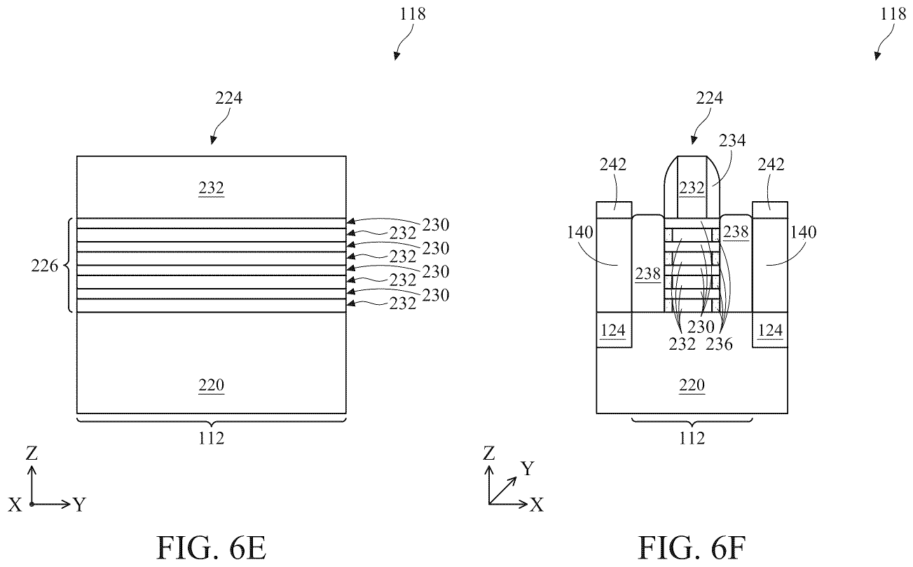

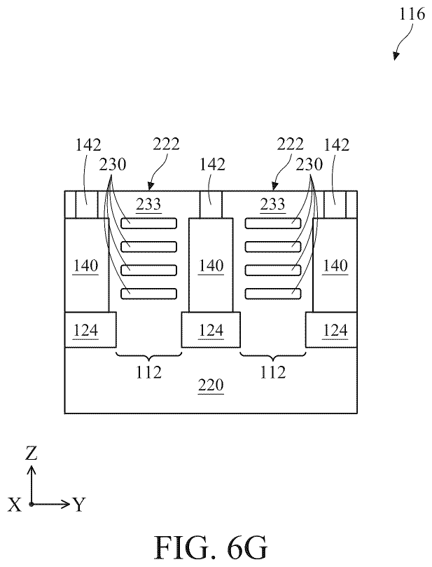

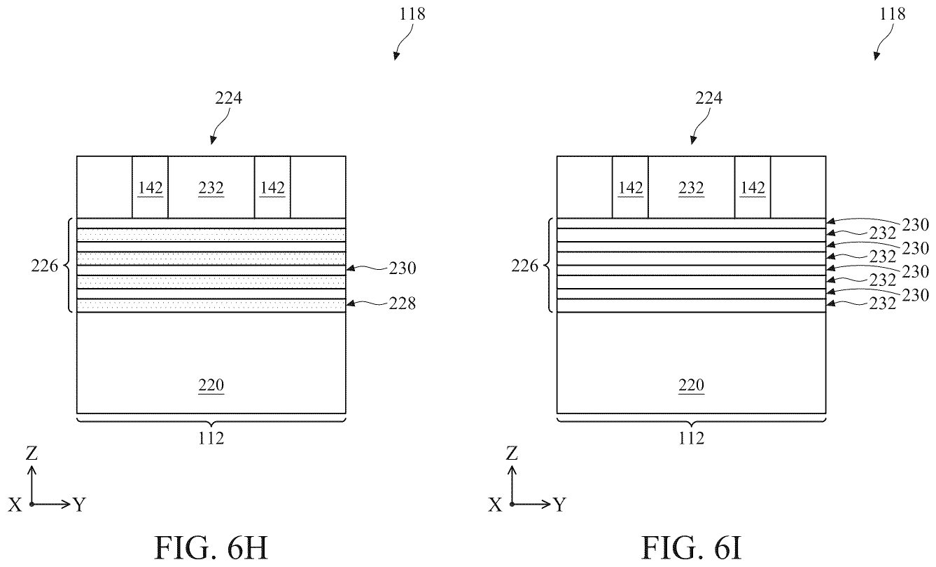

FIG. 6A is a sectional view of the semiconductor structure 100 in the window 118 of FIG. 1 cut along AA′ of FIG. 1 or FIG. 5B; FIG. 6B is a sectional view of the semiconductor structure 100 in the window 118 of FIG. 1 cut along BB′ of FIG. 1 or FIG. 5B; FIG. 6C is a sectional view of the semiconductor structure 100 in the window 116 of FIG. 1 cut along CC′ of FIG. 1 or FIG. 5A; and FIG. 6D is a sectional view of the semiconductor structure 100 in the window 116 of FIG. 1 cut along DD′ of FIG. 1 or FIG. 5A, constructed in accordance with some embodiments. Note that only substrate, active regions, isolation features and gate stacks are illustrated in those figures. Other features, such as interconnect structure and passivation layer are to be described later. Note that FIGS. 6A and 6B are directed to the structure in the seal ring region 104 while FIGS. 6C and 6D are directed to the structure in the circuit region 102.

In FIG. 6A, the semiconductor layer stack 226 is formed on a substrate 220. In the depicted embodiment, substrate 220 includes silicon. Additionally, or alternatively, substrate 220 includes another elementary semiconductor, such as germanium; a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. Alternatively, substrate 220 is a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods. Substrate 220 can include various doped regions depending on design requirements of the semiconductor structure 100. In the depicted embodiment, substrate 220 includes various doped features, such as a p-type doped region (referred to hereinafter as a p-well), which can be configured for n-type gate-all-around (GAA) transistors, and an n-type doped region (referred to hereinafter as an n-well), which can be configured for p-type GAA transistors. N-type doped regions are doped with n-type dopants, such as phosphorus, arsenic, other n-type dopant, or combinations thereof. P-type doped regions are doped with p-type dopants, such as boron, indium, other p-type dopant, or combinations thereof. In some implementations, substrate 220 includes doped regions formed with a combination of p-type dopants and n-type dopants. The various doped regions can be formed directly on and/or in substrate 220, for example, providing a p-well structure, an n-well structure, a dual-well structure, a raised structure, or combinations thereof. An ion implantation process, a diffusion process, and/or other suitable doping process can be performed to form the various doped regions.

In some embodiments, the substrate 220 may be a bulk silicon (Si) substrate. Alternatively, substrate 220 may include elementary semiconductor, such as germanium (Ge); a compound semiconductor, such as silicon carbide (SIC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. In some implementations, the substrate 220 includes one or more group III-V materials, one or more group II-VI materials, or combinations thereof. In still some instances, the substrate 220 is a semiconductor-on-insulator substrate, such as a silicon-on-insulator (SOI) substrate, a silicon germanium-on-insulator (SGOI) substrate, or a germanium-on-insulator (GeOI) substrate. In still some embodiments, the substrate 220 may be diamond substrate or a sapphire substrate.

A semiconductor layer stack 226 is formed over substrate 220, semiconductor layer stack 226 is patterned to form active regions, such as 112, and the gate stack 114 is formed on the active region 112. Note that the gate stack 114 within the seal ring region 104 is different from a gate stack in the circuit region 102 or the PD lane 106, therefore being referred with a numeral 224 herein. Semiconductor layer stack 226 includes semiconductor layers 228 and semiconductor layers 230 stacked vertically (e.g., along the z-direction) in an interleaving or alternating configuration from a surface of substrate 220. In some embodiments, semiconductor layers 228 and semiconductor layers 230 are epitaxially grown in the depicted interleaving and alternating configuration. For example, a first one of semiconductor layers 228 is epitaxially grown on substrate, a first one of semiconductor layers 230 is epitaxially grown on the first one of semiconductor layers 228, a second one of semiconductor layers 228 is epitaxially grown on the first one of semiconductor layers 230, and so on until semiconductor layers stack 226 has a desired number of semiconductor layers 228 and semiconductor layers 230. In such embodiments, semiconductor layers 228 and semiconductor layers 230 can be referred to as epitaxial layers. In some embodiments, epitaxial growth of semiconductor layers 228 and semiconductor layers 230 is achieved by a molecular beam epitaxy (MBE) process, a chemical vapor deposition (CVD) process, a metalorganic chemical vapor deposition (MOCVD) process, other suitable epitaxial growth process, or combinations thereof.

A composition of semiconductor layers 228 is different than a composition of semiconductor layers 230 to achieve etching selectivity and/or different oxidation rates during subsequent processing. In some embodiments, semiconductor layers 228 have a first etch rate to an etchant and semiconductor layers 230 have a second etch rate to the etchant, where the second etch rate is less than the first etch rate. In some embodiments, semiconductor layers 228 have a first oxidation rate and semiconductor layers 230 have a second oxidation rate, where the second oxidation rate is less than the first oxidation rate. In the depicted embodiment, semiconductor layers 228 and semiconductor layers 230 include different materials, constituent atomic percentages, constituent weight percentages, thicknesses, and/or characteristics to achieve desired etching selectivity during an etching process, such as an etching process implemented to form suspended channel layers in channel regions of semiconductor structure 100. For example, where semiconductor layers 228 include silicon germanium and semiconductor layers 230 include silicon, a silicon etch rate of semiconductor layers 230 is less than a silicon germanium etch rate of semiconductor layers 228 in the etching process of the channel-release. In some embodiments, semiconductor layers 228 and semiconductor layers 230 can include the same material but with different constituent atomic percentages to achieve the etching selectivity and/or different oxidation rates. For example, semiconductor layers 228 and semiconductor layers 230 can include silicon germanium, where semiconductor layers 228 have a first silicon atomic percent and/or a first germanium atomic percent and semiconductor layers 230 have a second, different silicon atomic percent and/or a second, different germanium atomic percent. The present disclosure contemplates that semiconductor layers 228 and semiconductor layers 230 include any combination of semiconductor materials that can provide desired etching selectivity, desired oxidation rate differences, and/or desired performance characteristics (e.g., materials that maximize current flow), including any of the semiconductor materials disclosed herein.

In FIG. 6B, the gate structure 224, source and drain (collectively source/drain features) 238 are formed in the seal ring region 104. Note that only one active region 112 is illustrated in FIG. 6B and it is not intending to be limiting. The number of the active regions 112 in the seal ring region 104 can be any proper number, depending on the design consideration, sealing effect and other factors. In the disclosed structure, the first semiconductor layers 228 are removed with the second semiconductor layers 230 remained as channels (also referred to by numeral 230), the multiple channels 230 are vertically stacked over the substrate 220 and are connected to the source/drain features 238. The gate stack 224 includes one or more gate material referred by numeral 232. The gate stack 224 may include a gate dielectric layer and a gate electrode. In some embodiments, the gate material 232 includes polysilicon.

Gate spacers 234 are disposed on sidewalls of the gate stack 224. The gate spacers 234 include one or more dielectric material, such as silicon oxide, silicon nitride, silicon oxynitride or a combination thereof. The gate stack 224 is disposed on the semiconductor layer stack 226. In this case, the structure of the active region 112 and gate stack 224 in the seal ring region 104 is different from those in the circuit region 102 since the circuit region 102 includes GAA transistors, the first semiconductor layers 228 are removed to release channels, and the gate stack is extending down to wrap around the vertically stacked channels, which will be further described below. The seal ring structure in the seal ring region 104 may also include various cut features, such as active region cut features 140 and gate cut features 142, formed during double or multiple patterning processes. In some embodiments, the active region cut features 140 are dielectric features or a subset thereof are dielectric fins (relative to fin active regions) configured to tune pattern density and pattern uniformity to enhance to fabrication, such as CMP processes. The source and drain (or source/drain features) 238 are formed on the active region 112 contacting both the first semiconductor layers 228 and the second semiconductor layers 230.

The gate electrode layer may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAIN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed using ALD, PVD, CVD, e-beam evaporation, or other suitable process.

Source/drain features may include silicon (Si) doped with an n-type dopant, such as phosphorus (P) or arsenic (As) or silicon germanium (SiGe) doped with a p-type dopant, such as boron (B) or boron difluoride (BF₂). The sourced/drain contacts may include a silicide layer, a metal fill layer disposed over the silicide layer, and a barrier layer to separate the metal fill layer from the IMD layer. The barrier layer may include titanium nitride or tantalum nitride and functions to prevent electro-migration in the metal fill layer. The silicide layer may include titanium silicide, tantalum silicide, cobalt silicide, nickel silicide, or tungsten silicide. The silicide layer is disposed at the interface between the metal fil layer and the source/drain features to reduce contact resistance. The metal fill layer may include ruthenium (Ru), copper (Cu), nickel (Ni), cobalt (Co), tungsten (W), or other suitable metal material.

In FIGS. 6C and 6D, the circuit region 102 includes multi-channel devices, such as GAA transistors, are formed on the substrate 220. Multi-channel device includes multiple channels vertically stacked on the substrate 220 and a gate stack 114 extends to wrap around of and couple with each of the vertically stacked multiple channels. Note that the gate stack in the circuit region 102 is referred by a numeral 222 due to different compositions. The source and drain 238 are disposed on opposite sides of the gate stack 222 and connect each of the vertically stacked multiple channels 230. In the disclosed embodiment, the first semiconductor layers 228 are removed to release channels, the second semiconductor layers 230 function as channels of multi-channel transistors. The gate stack 222 includes a gate dielectric layer and a gate electrode, collectively referred to as gate materials by numeral 233. Note that the gate materials 233 may be different from the gate material 232 according to some embodiments. For example, the gate materials 233 include a gate dielectric layer (that further includes a high-k dielectric material) and a gate electrode (that further includes metal). The gate stack 222 is extending to wrap around each of the channels 230. The source/drain features 238 are isolated from the gate stack 222 by inner spacers 236 and the gate spacers 234. The inner spacers 236 include one or more dielectric material, such as silicon oxide, silicon nitride, silicon oxynitride or a combination thereof. The formation of the disclosed structure includes forming dummy gates by depositing (such as polysilicon) and patterning; forming source/drain features by etching to recess source/drain regions, laterally recessing the first semiconductor layers 228, forming inner spacers 236 by deposition and anisotropic etching, and epitaxial growth to form source/drain features 238; forming interlayer dielectric (ILD) layer; removing the dummy gates by selective etching; selectively removing the first semiconductor layers 228 to release the channels; and forming metal gates to wrap around the channels by deposition. The subset of the above operations to form gate stacks 222 is referred to as gate replacement. The replaced gate stacks 222 includes high-k dielectric material and metal.

Back to FIGS. 6A and 6B, since gate stack 224 are not formed by the gate replacement, the gate materials of the gate stacks 224 are different from the gate material of the gate stacks 222. For example, the gate stacks 224 include polysilicon. In some embodiments, the gate stacks in the seal ring region 104 are partially replaced, such as only the dummy gates are replaced but the first semiconductor layers 228 are not removed and the channels are not released in the seal ring region 104. In this case, the gate stacks 224 have the same composition as the gate stack 222 but different configuration, as illustrated in FIGS. 6A, 6B, 6C and 6D. In some embodiments, the gate stacks 224 in the seal ring region 104 are similarly formed as the gate stack 222 in the circuit region 102. Particularly, the dummy gates are replaced and the first semiconductor layers 228 are removed and the channels are released in the seal ring region 104, as illustrated in FIGS. 6E and 6F. In some embodiments, the gate cut features 142 may be formed before the dummy gates, after the dummy gates or after the gate replacement. In the above-described various embodiments, the gate stacks 224 are either formed by the gate replacement or alternatively formed without gate replacement, various parameters of the seal ring structure, such as width and pitch of active regions 112, may vary randomly or periodically or vary according to other consideration, such as illustrated in FIG. 2E.

In other embodiments, the gate cut features 142 may be configured differently in the circuit region 102, such as illustrated in FIG. 6G. FIG. 6G is similar to FIG. 6D except for that the gate cut features 142 are configured differently. In the disclosed embodiment, the gate cut features 142 are formed on various fin cut features 140. The gate stack 224 is cut into multiple segments.

In other embodiments, the gate cut features 142 may be configured differently in the seal ring region 104, such as illustrated in FIGS. 6H and 6I. FIG. 6H is similar to FIG. 6A except for that the gate cut features 142 are configured differently. FIG. 6I is similar to FIG. 6E except for that the gate cut features 142 are configured differently.

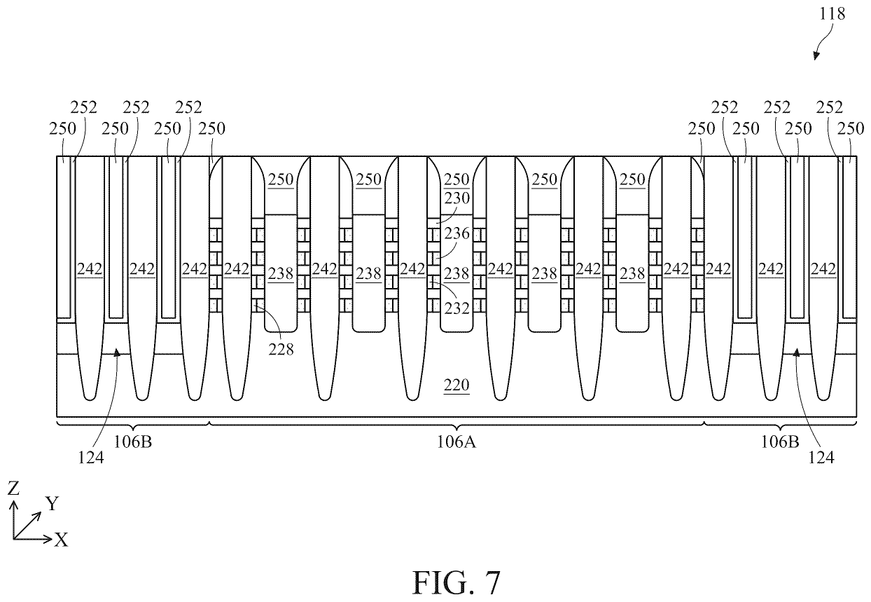

Now back to the structure in the PD lane 106. The PD lane 106 is further described with reference to FIGS. 7 and 8A through 8D, and 9A through 9D.

FIG. 7 is a sectional view of the semiconductor structure 100 within the PD lane 106 in the window portion 118 of FIG. 1 or FIG. 3A cut through along AA′ in FIG. 3A according to some embodiments.

As described above, the PD lane in the window portion 118 includes a central region 106A and side regions 106B. The central region 106A includes both active regions 112 and gate stacks 114 while the side regions 106B are free of active region 112 and only include gate stacks 114 formed on the isolation features 124. However, the gate stacks 114 are dielectric features, such as SiN feature, formed by a proper method. Therefore, those dielectric gate stacks are referred as dielectric gate stacks with the numeral 242. In the disclosed embodiment, the dielectric gate stacks in the PD lane 106 are separately formed. In some embodiments, the gate stacks 114 as dielectric features are formed by a gate cut process (described above) and are simultaneously formed with other gate cut features 142 in the same gate cut process. In furtherance of the embodiment, the dielectric gate stacks 242 are extending down deep into the substrate 220 and below the bottom surface of the isolation features 124. The structure further includes an interlayer dielectric (ILD) layer 250 formed by a proper method, such as a procedure that includes and deposition and chemical mechanical polishing (CMP). The structure further includes an etch stop layer (ESL) 252 formed underlying the ILD layer 250 to provide etch selectivity. In various embodiments, the ILD layer 250 includes silicon oxide, low k dielectric material, other suitable dielectric materials or a combination thereof. The ESL 252 includes one or more dielectric material different from the ILD layer 250. For example, the ESL 252 includes SiN, SiON, other dielectric materials or a combination thereof. Note that the number gate stacks in the central region 106A and the side regions 106B may not match those in FIG. 3A since this is only for illustration and not intended to be limiting.

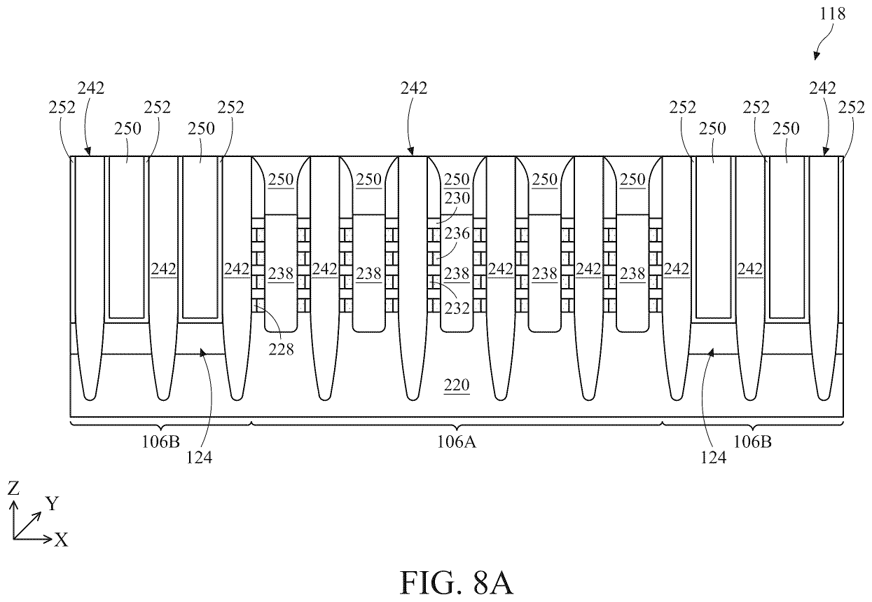

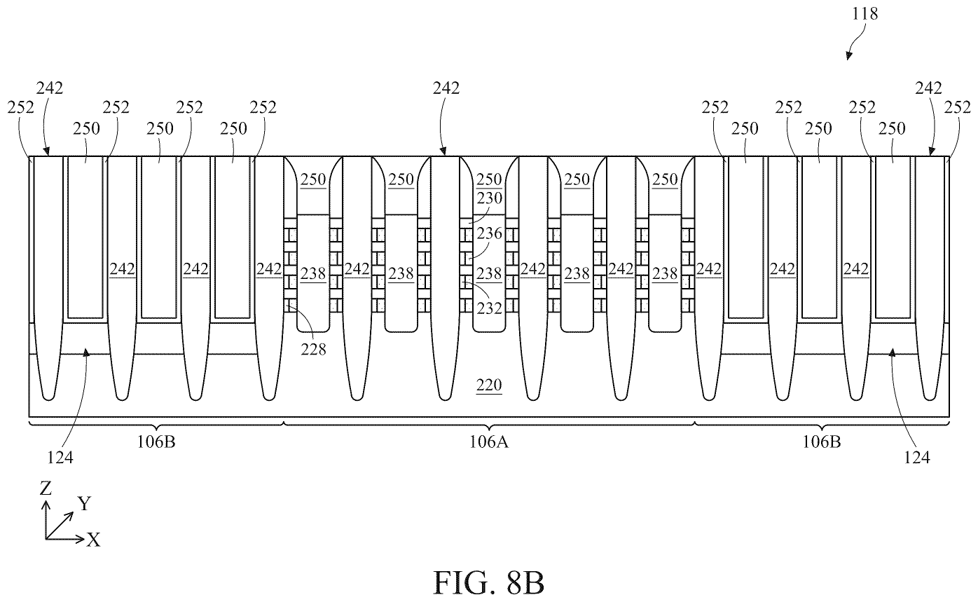

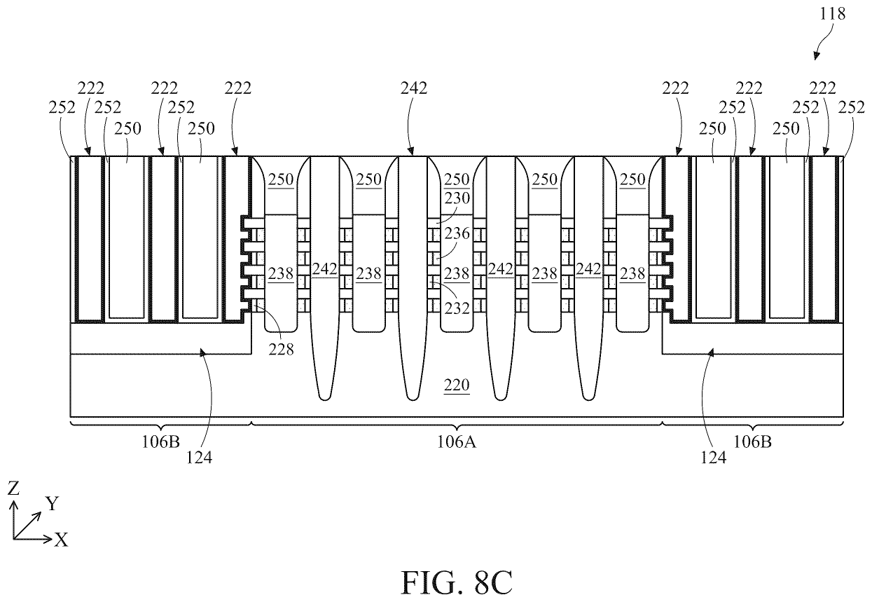

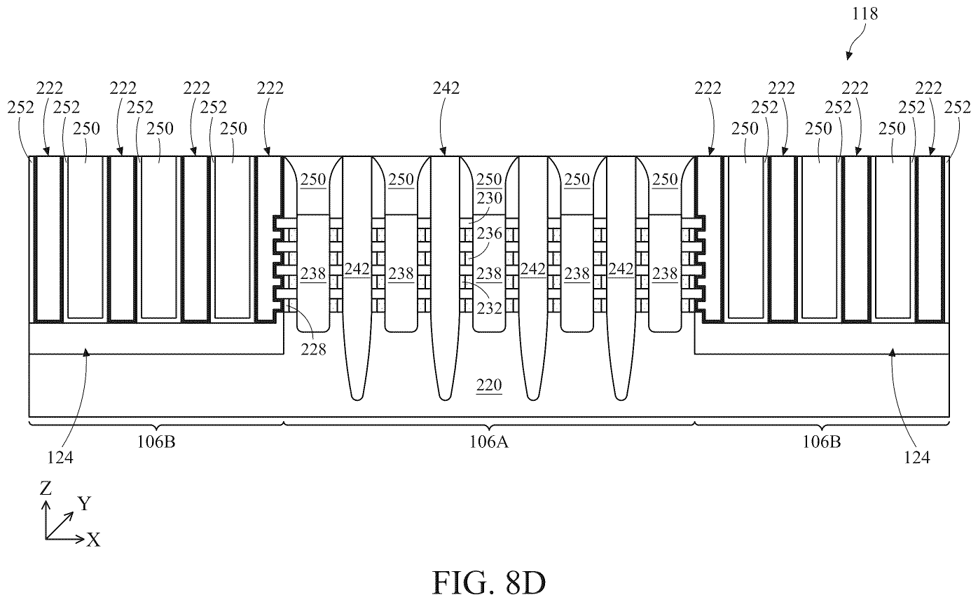

FIG. 8A is a sectional view of the semiconductor structure 100 within the PD lane 106 in the window portion 118 of FIG. 1 or FIG. 3A cut through along AA′ in FIG. 3A according to some embodiments.

The semiconductor structure 100 in FIG. 8A is similar to the semiconductor structure 100 in FIG. 7A. The PD lane 106 in the window portion 118 includes a central region 106A and side regions 106B. The central region 106A includes both active regions 112 and gate stacks 114 while the side regions 106B are free of active region 112 and only include gate stacks 114 formed on the isolation features 124. However, the gate stacks 114 are dielectric features, such as SiN feature, formed by a proper method. In the disclosed embodiment, the gate stacks 114 as dielectric features are formed by a separate procedure and are referred as dielectric gate stacks with the numeral 242. In furtherance of the embodiment, the dielectric gate stacks 242 are extending down deep into the substrate 220 and below the bottom surface of the isolation features 124. The structure further includes an interlayer dielectric (ILD) layer 250 formed by a proper method, such as a procedure that includes and deposition and chemical mechanical polishing (CMP). The structure further includes an etch stop layer (ESL) 252 formed underlying the ILD layer 250 to provide etch selectivity. In various embodiments, the ILD layer 250 includes silicon oxide, low k dielectric material, other suitable dielectric materials or a combination thereof. The ESL 252 includes one or more dielectric material different from the ILD layer 250. For example, the ESL 252 includes SiN, SiON, other dielectric materials or a combination thereof. Note that the number gate stacks in the central region 106A and the side regions 106B may not match those in FIG. 3A since this is only for illustration and not intended to be limiting.

FIG. 8B is a sectional view of the semiconductor structure 100 within the PD lane 106 in the window portion 118 of FIG. 1 and cut through along AA′ in FIG. 3B or 3C according to some embodiments. FIG. 8B is similar to FIG. 8A even though those structures are different, such as being different in top views. Similar descriptions are not repeated herein for simplicity.

FIG. 8C is a sectional view of the semiconductor structure 100 within the PD lane 106 in the window portion 118 of FIG. 1 cut through along AA′ in FIG. 3D according to some embodiments. FIG. 8D is similar to FIG. 8A. However, the gate stacks in the side regions 106B are metal gate stacks similar to those in the circuit region 102. Therefore, those gate stacks in the side regions 106B are referred to as metal gate stacks with the numeral 222. Similar descriptions are not repeated herein for simplicity.

FIG. 8D is a sectional view of the semiconductor structure 100 within the PD lane 106 in the window portion 118 of FIG. 1 cut through along AA′ in FIG. 3E or 3F according to some embodiments. FIG. 8D is similar to FIG. 8B. However, the gate stacks in the side regions 106B are metal gate stacks similar to those in the circuit region 102. Therefore, those gate stacks in the side regions 106B are referred to as metal gate stacks with the numeral 222. Similar descriptions are not repeated herein for simplicity.

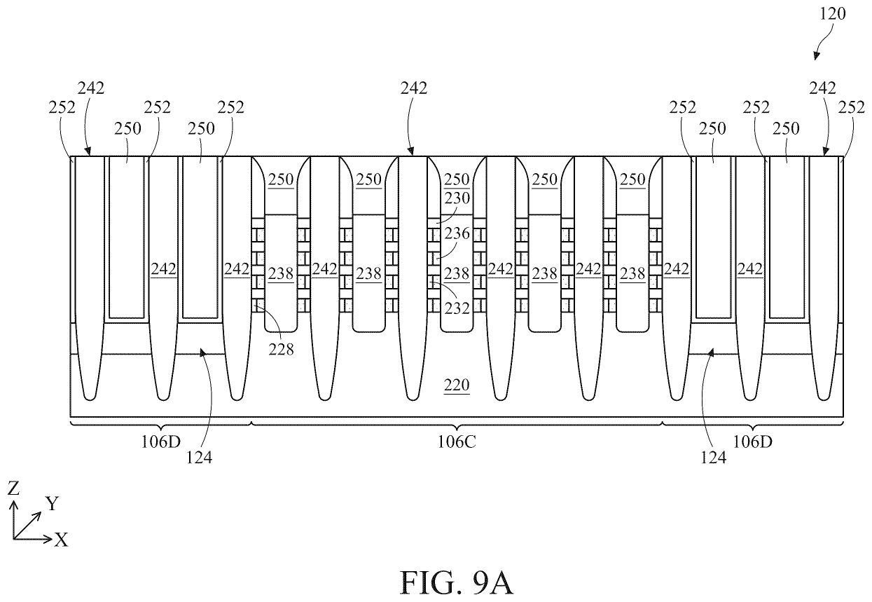

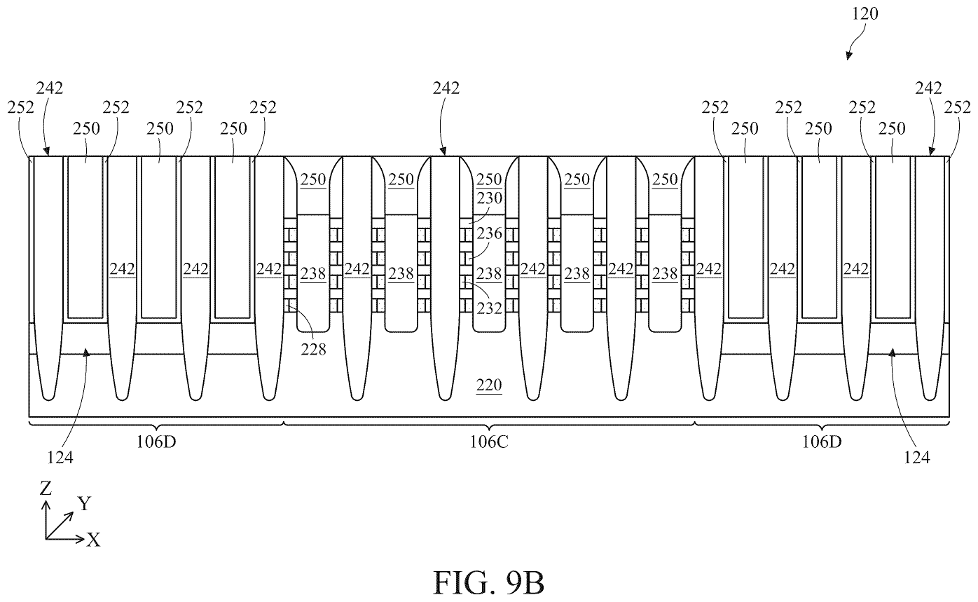

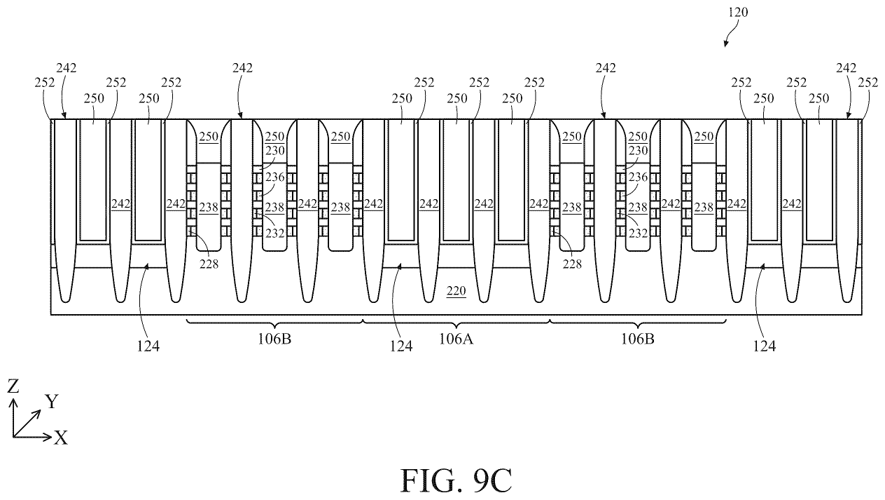

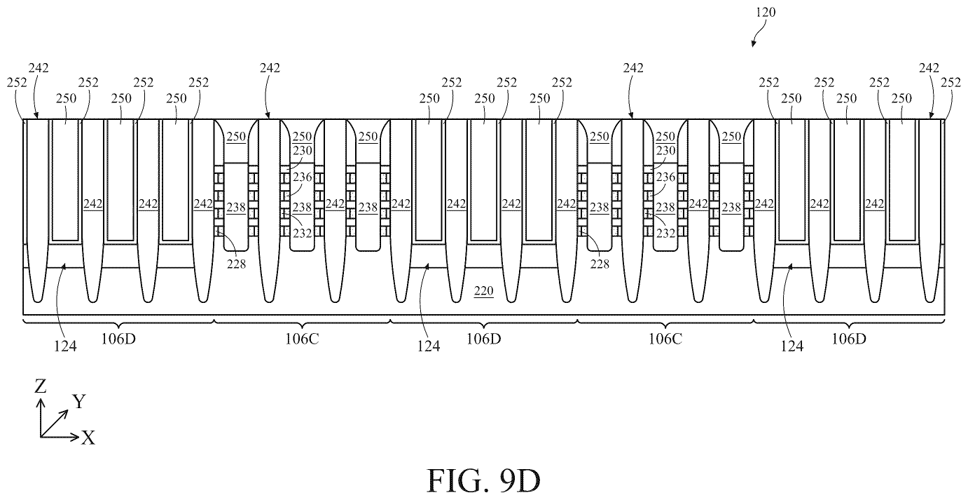

FIG. 9A is a sectional view of the semiconductor structure 100 within the PD lane 106 in the window portion 120 of FIG. 1 or FIG. 4A cut through along AA′ in FIG. 4A according to some embodiments. Note that

The PD lane 106 in the window portion 120 includes a first region 106C and second regions 106D. The first region 106C includes both active regions 112 and gate stacks 114 while the second regions 106D are free of active region 112 and only include gate stacks 114 formed on the isolation features 124. However, the gate stacks 114 in both first regions 106C and second regions 106D are dielectric features, such as SiN feature, formed by a proper method. In the disclosed embodiment, the gate stacks 114 as dielectric features are formed by a procedure that includes patterning, deposition and CMP. Therefore, those dielectric gate stacks are referred as dielectric gate stacks with the numeral 242. In furtherance of the embodiment, the dielectric gate stacks 242 are extending down deep into the substrate 220 and below the bottom surface of the isolation features 124. The structure further includes an ILD layer 250 formed by a proper method, such as a procedure that includes and deposition and CMP. The structure further includes an ESL 252 formed underlying the ILD layer 250 to provide etch selectivity. In various embodiments, the ILD layer 250 includes silicon oxide, low k dielectric material, other suitable dielectric materials or a combination thereof. The ESL 252 includes one or more dielectric material different from the ILD layer 250. For example, the ESL 252 includes SiN, SiON, other dielectric materials or a combination thereof.

FIG. 9B is a sectional view of the semiconductor structure 100 within the PD lane 106 in the window portion 120 of FIG. 1 and cut through along AA′ in FIG. 4B or 4C according to some embodiments. FIG. 9B is similar to FIG. 9A even though those structures are different, such as being different in top views. Similar descriptions are not repeated herein for simplicity.

FIG. 9C is a sectional view of the semiconductor structure 100 within the PD lane 106 in the window portion 120 of FIG. 1 cut through along AA′ in FIG. 4D according to some embodiments. FIG. 8D is similar to FIG. 8A. However, the PD lane 106 in the window portion 120 includes a multiple of first regions 106C and a multiple of second regions 106D. Similar descriptions are not repeated herein for simplicity.

FIG. 9D is a sectional view of the semiconductor structure 100 within the PD lane 106 in the window portion 120 of FIG. 1 cut through along AA′ in FIG. 4E or 4F according to some embodiments. FIG. 9D is similar to FIG. 9B. However, the PD lane 106 in the window portion 120 includes a multiple of first regions 106C and a multiple of second regions 106D. Similar descriptions are not repeated herein for simplicity.

The semiconductor structure 100 in various embodiments may be formed with other technologies, such as system on chip (SoC), integrated fan out (InFO) packaging technologies, package-on-package (POP), Chip-on-Wafer-on-Substrate (CoWoS), and other suitable structure/technology.

As described before, after formation of active regions, channels, source/drain features and gate stacks, interconnect structure and passivation layer are further formed on. Various features in the seal ring region 104 are also designed differently from those in the circuit region 102 as further described below in detail.

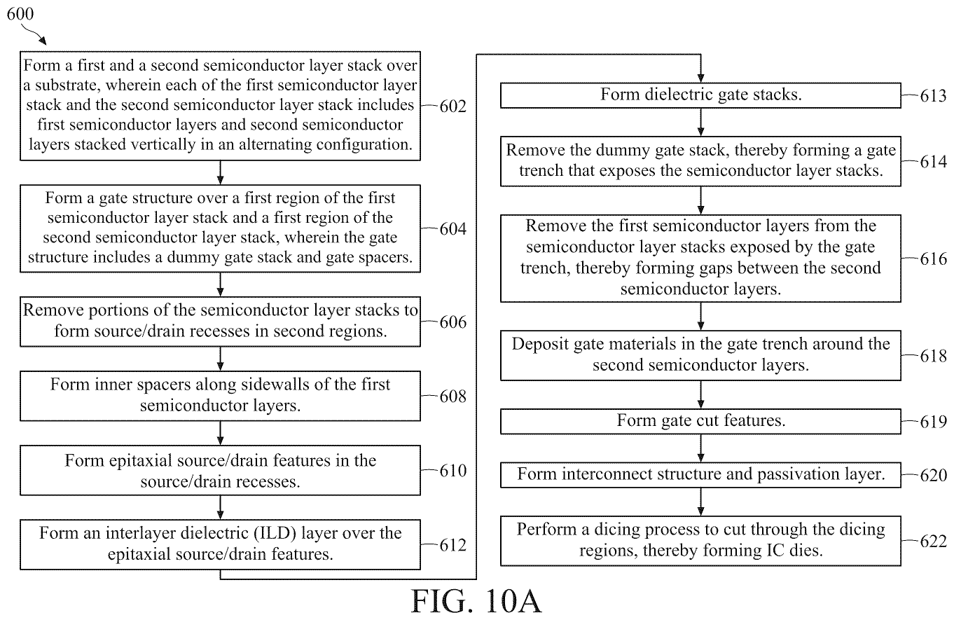

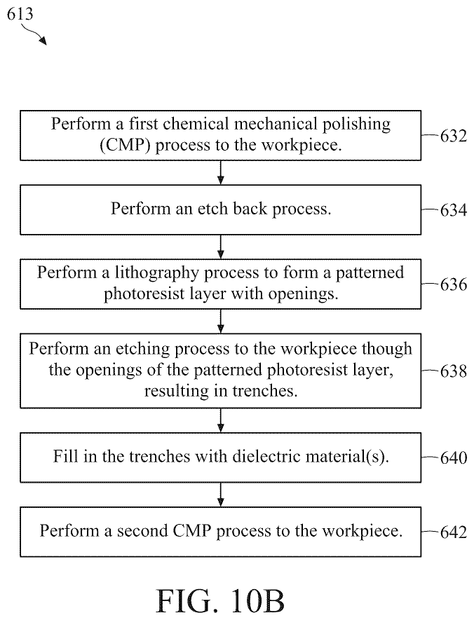

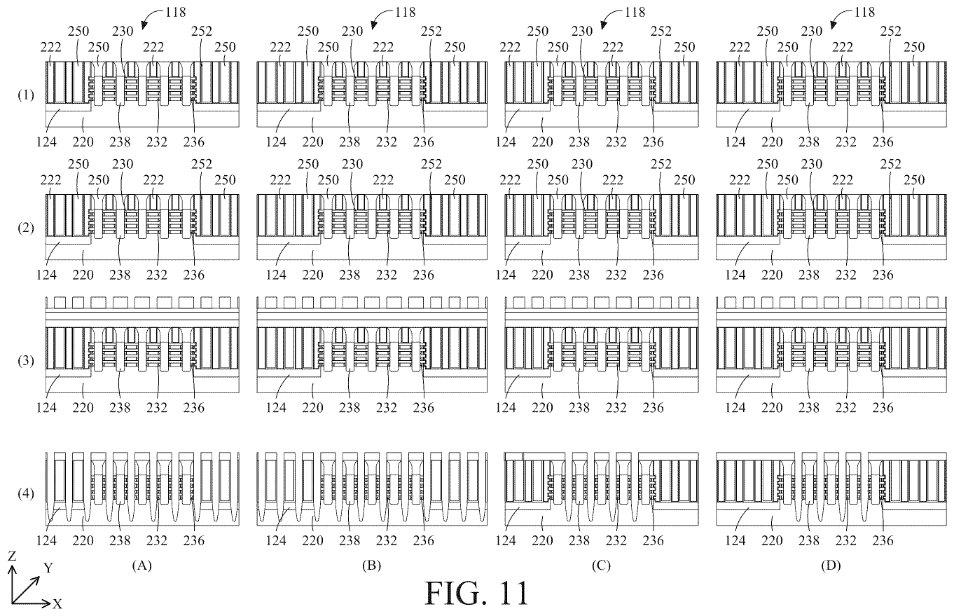

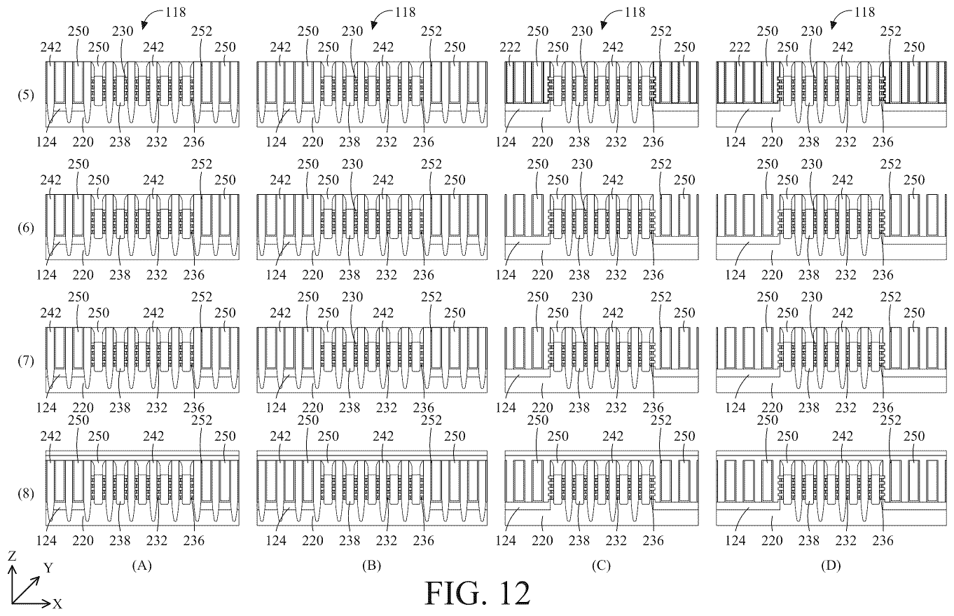

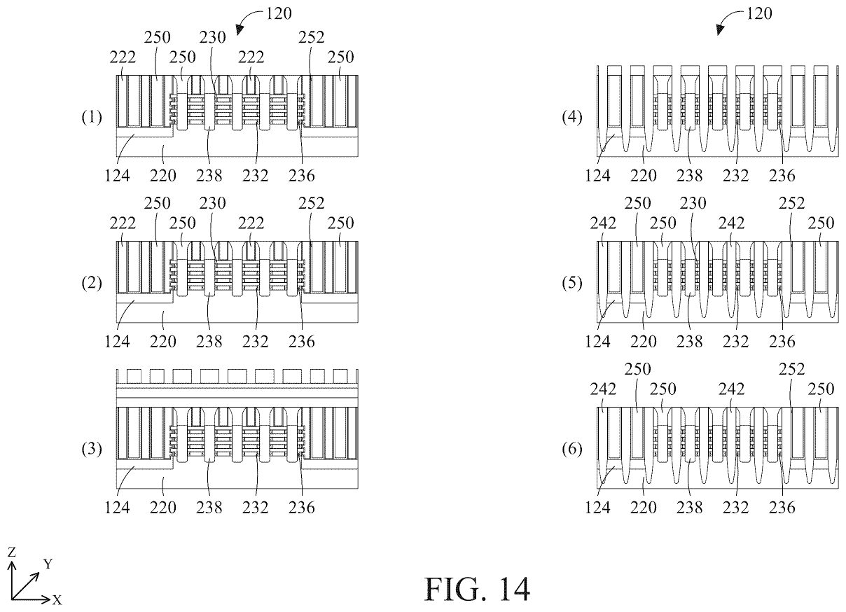

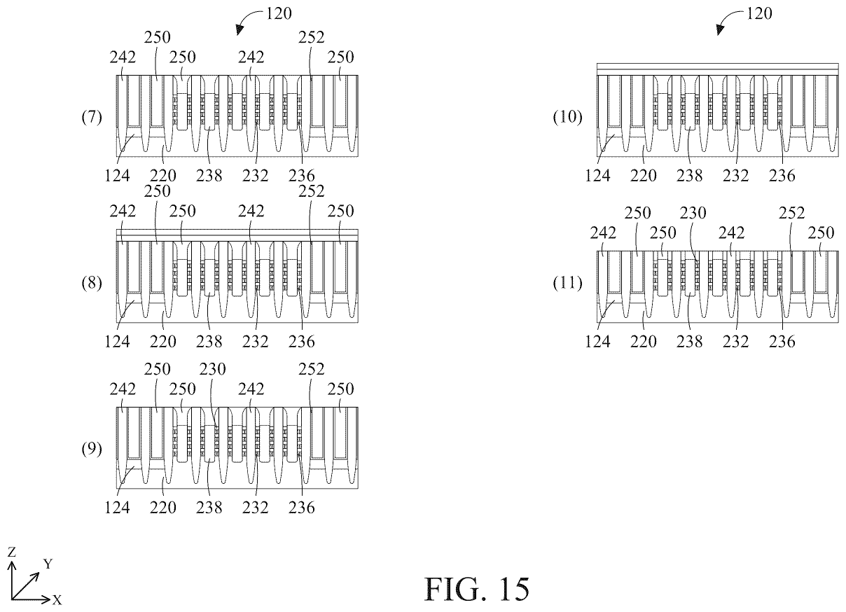

The method 600 to form the semiconductor structure 100 is further described with reference to FIG. 10A as a flowchart of a method 600 constructed in accordance with some embodiments. FIG. 10B as a flowchart of a method 613 to form dielectric gate stacks constructed in accordance with some embodiments. FIGS. 11 through 15 are sectional views of the semiconductor structure 100 at different fabrication stages constructed according to various embodiments. Particularly, the columns (A) in FIGS. 11, 12 and 13 are associated with the structure in FIG. 3A; the columns (B) in FIGS. 11, 12 and 13 are associated with the structure in FIG. 3B or 3C; the columns (C) in FIGS. 11, 12 and 13 are associated with the structure in FIG. 3D; the columns (D) in FIGS. 11, 12 and 13 are associated with the structure in FIG. 3E or 3F; and FIGS. 14 and 15 are associated with the structure in FIG. 4A, 4B, 4C or 4D. The rows (1) through (11) are associated with various operations of the method 613 and other operations in the method 600. The methods 600 and 613 are described with reference to FIGS. 10A, 10B and 11 through 15.

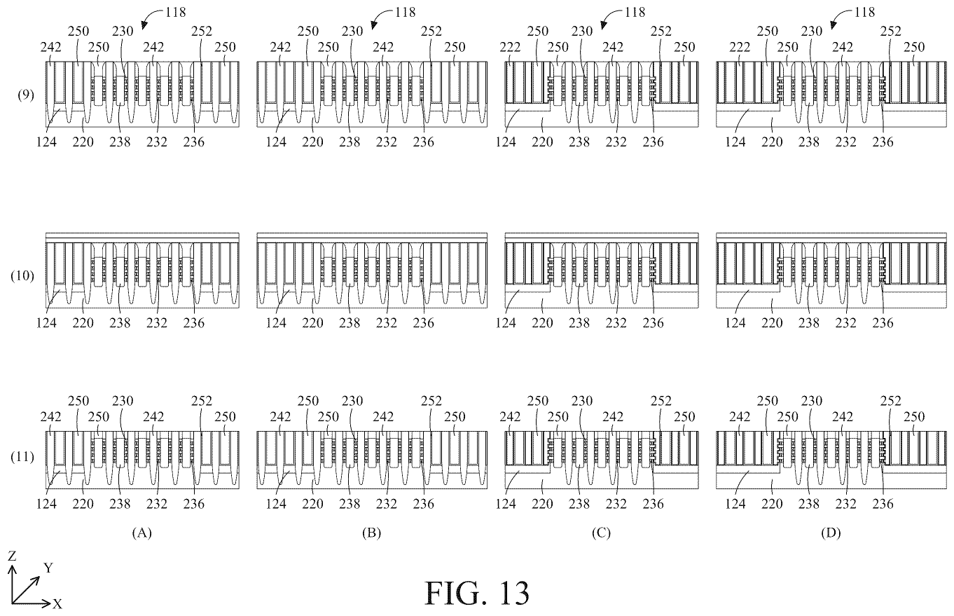

In some embodiments, method 600 fabricates a semiconductor structure with multi-channel devices that includes p-type GAA transistors and n-type GAA transistors. At block 602, a first semiconductor layer stack and a second semiconductor layer stack are formed over a substrate. Each of the first semiconductor layer stack and the second semiconductor layer stack include first semiconductor layers and second semiconductor layers stacked vertically in an alternating configuration. At block 604, a gate structure is formed over a first region of the first semiconductor layer stack and a first region of the second semiconductor layer stack. The gate structure includes a dummy gate stack and gate spacers. At block 606, portions of the first semiconductor layer stack in second regions and portions of the second semiconductor layer stack in second regions are removed to form source/drain recesses. At block 608, inner spacers are formed along sidewalls of the first semiconductor layers in the first semiconductor layer stack and the second semiconductor layer stack. At block 610, epitaxial source/drain features are formed in the source/drain recesses. At block 612, an interlayer dielectric (ILD) layer is formed over the epitaxial source/drain features. At block 613, dielectric gate stacks, such as dielectric gate stacks 242 in the PD lane 106, are formed. The block 613 includes a procedure that includes patterning, deposition and CMP. The process at block 613 will be further described below in details. At block 614, the dummy gate stack is removed, thereby forming a gate trench that exposes the first semiconductor layer stack in a p-type gate region and the second semiconductor layer stack in n-type gate region, as illustrated in the row (6) of FIGS. 12 and 14. At block 616, the first semiconductor layers are removed from the first semiconductor layer stack and the second semiconductor layer stack exposed by the gate trench, thereby forming gaps between the second semiconductor layers, as illustrated in the row (7) of FIGS. 12 and 15. At block 618, various gate materials are deposited into the gate trench to form gate stack, as illustrated in the row (8) of FIGS. 12 and 15, the row (9) of FIGS. 13 and 15. The operations at block 618 includes deposition and CMP. At block 619, dielectric gate stacks are formed, as illustrated in the rows (10) and (11) of FIGS. 13 and 15. At block 620, an interconnect structure and a passivation layer are formed. At block, 622, the semiconductor structure (workpiece) is cut through the dicing lane (PD lane) using a proper dicing method, such as plasma dicing. Additional processing is contemplated by the present disclosure. Additional steps can be provided before, during, and after method 600, and some of the steps described can be moved, replaced, or eliminated for additional embodiments of method 600. The discussion that follows illustrates various embodiments of nanowire-based integrated circuit devices that can be fabricated according to method 600.

The method 613 to form the dielectric gate stacks in the semiconductor structure 100 is further described with reference to FIG. 10B as a flowchart, constructed in accordance with some embodiments.

In some embodiments, method 613 includes a block 632 to perform a CMP process to the semiconductor structure 100, especially to the ILD layer, to planarize the top surface of the semiconductor structure 100, as illustrated in the row (1) of FIGS. 11 and 14. At block 634, perform an etch back process to the semiconductor structure 100, as illustrated in the row (2) of FIGS. 11 and 14. At block 636, form a patterned photoresist layer with openings by a lithography process, as illustrated in the row (3) of FIGS. 11 and 14. The openings define the regions, such as the dicing regions wherein the gate cut features to be formed. In some embodiments, a hard mask may be used as an etch mask. In this case, the openings of the patterned photoresist layer are first transferred to the hard mask by an etching process. At 638, perform an etch process to the semiconductor structure 100 through the openings of the patterned photoresist layer, resulting in trenches, such as in the dicing region, as illustrated in the row (4) of FIGS. 11 and 14. The trenches extend below the bottom surface of isolation structure 124. At 640, fill in one or more dielectric materials in the trenches to form the dielectric gate stacks 242 including dielectric gate stacks 242 in the dicing region 106, as illustrated in the row (5) of FIGS. 12 and 14. In some embodiments, the dielectric material is silicon nitride. At 642, perform another CMP process to remove excessive dielectric material and planarize the top surface of the semiconductor structure 100, as illustrated in the row (5) of FIGS. 12 and 14.

The present disclosure provides the dicing lane with active regions and gate stacks configured with effect to reduce metal residues and enhance the dicing performance. The active regions and gate stacks in the dicing lane are designed and configured differently from those in the circuit regions and seal ring region in terms of dimensions, orientations, composition and other parameters.

Although not intended to be limiting, embodiments of the present disclosure provide one or more of the following advantages. For example, embodiments of the present disclosure provide a seal ring region enclosing a circuit region. The seal ring region includes a sealing region and a transition region between the sealing region and the circuit region. The transition region includes straight conductive lines parallel to an edge of the seal ring region and disposed around the circuit region. The transition region smooths the transition from the circuit region of a higher pattern density to a seal ring region of a low pattern density. Therefore, reducing the over etching or dishing issues during the subsequent processes. In some embodiments, all transition lines in the transition region are parallel to the conductive lines in the circuit region. In some embodiments, each of the transition lines has a width greater than widths of the conductive lines in the circuit region and less than widths of the conductive lines in the seal rings. In some embodiments, first transition lines in the transition region of a first metal layer are substantially perpendicular to second transition lines in the transition region of a second metal layer.

In one example aspect, the present disclosure is directed to a semiconductor structure that includes a substrate having a circuit region and a seal ring region surrounding the circuit region, and a dicing lane surrounding the seal ring region, wherein the dicing lane includes a first dicing region and a second dicing region disposed on both sides of the first dicing region; first active regions formed in the circuit region; first gate stacks formed on the first active region in the circuit region, the first gate stacks including metal electrodes; second active regions formed in the first dicing region; dielectric structures formed on the second active regions in the first dicing region; and second gate stacks formed on an isolation feature in the second dicing region.

In another example aspect, the present disclosure is directed to a semiconductor structure that includes a substrate having a circuit region and a seal ring region surrounding the circuit region, and a dicing lane surrounding the seal ring region, wherein the dicing lane includes a first dicing region and a second dicing region disposed on both sides of the first dicing region; first active regions formed in the circuit region; first gate stacks formed on the first active region in the circuit region; second active regions formed in the first dicing region; first dielectric gate stacks formed on the second active regions in the first dicing region; and second dielectric gate stacks formed on an isolation feature in the second dicing region, wherein the first and second dielectric gate stacks are dielectric features, and the first gate stacks are metal gate stacks.

In yet another example aspect, the present disclosure is directed to a method making a semiconductor structure. The method includes providing a substrate having a circuit region and a seal ring region surrounding the circuit region, and a dicing lane surrounding the seal ring region, wherein the dicing lane includes a first dicing region and a second dicing region disposed on both sides of the first dicing region; forming first active regions in the circuit region, and second active regions in the first dicing region; forming first gate stacks on the first active region in the circuit region, first dielectric gate stacks on the second active regions in the first dicing region, and second dielectric gate stacks on an isolation feature in the second dicing region, wherein the first and second dielectric gate stacks are dielectric features, and the first gate stacks are metal gate stacks; and dicing the substrate along the dicing lane.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having a circuit region and a seal ring region surrounding the circuit region, and a dicing lane surrounding the seal ring region, wherein the dicing lane includes a first dicing region and a second dicing region disposed on both sides of the first dicing region;
first active regions formed in the circuit region;
first gate stacks formed on the first active region in the circuit region, the first gate stacks including metal electrodes;
second active regions formed in the first dicing region;
dielectric structures formed on the second active regions in the first dicing region; and
second gate stacks formed on an isolation feature in the second dicing region.

2. The semiconductor structure of claim 1, wherein the second dicing region is free of active region.

3. The semiconductor structure of claim 1, wherein
the first and second active regions are longitudinally oriented along a first direction;
the first gate stacks and the dielectric structures are longitudinally oriented along a second direction being orthogonal to the first direction;
the second dicing region further includes third gate stacks longitudinally oriented along the first direction; and
the second gate stacks longitudinally are oriented along the second direction.

4. The semiconductor structure of claim 3, wherein the third gate stacks are connected to the second gate stacks.

5. The semiconductor structure of claim 3, wherein
the second gate stacks include a first gate stack, a second gate stack and a third gate stack;
the third gate stacks include a first subset of the third gate stacks distributed between the first gate stack and the second gate stack, and a second subset of the third gate stacks distributed between the second gate stack and the third gate stack; and
the first subset of the third gate stacks span between the first gate stack and the second gate stack.

6. The semiconductor structure of claim 5, wherein the first subset of the third gate stacks are aligned with the second subset of the third gate stacks along the first direction.

7. The semiconductor structure of claim 5, wherein the first subset of the third gate stacks and the second subset of the third gate stacks are configured in a staggered mode along the second direction.

8. The semiconductor structure of claim 1, wherein
the dicing lane further includes a third dicing region and a fourth dicing region cascaded configured with the first and second dicing regions;
the third dicing region includes third gate stacks longitudinally oriented along the second direction; and
the fourth dicing region include fourth gate stacks longitudinally oriented along the second direction and fifth gate stacks longitudinally oriented along the first direction.

9. The semiconductor structure of claim 8, wherein the fourth gate stacks are connected to the fifth gate stacks.

10. The semiconductor structure of claim 1, wherein
the first active regions include a first width W1;
second active regions include a second width W2; and
the second width is greater than the first width.

11. The semiconductor structure of claim 1, wherein the seal ring region includes third active regions longitudinally oriented along the first direction and third gate stacks longitudinally oriented to be in parallel with the third active regions.

12. The semiconductor structure of claim 11, wherein the third gate stacks are landing on the third active region with margins such that a first and second longitudinal edges of each of the third gate stacks are within a first and second longitudinal edges of a corresponding one of the third active regions.

13. The semiconductor structure of claim 12, wherein the third gate stacks include polysilicon.

14. The semiconductor structure of claim 1, further comprising an isolation structure surrounding each of the first and second active regions, wherein
the first and second active regions are protruded above a top surface of the isolation structure; and
the dielectric structures are vertically extending below a bottom surface of the isolation structure.

15. A semiconductor structure, comprising:
a substrate having a circuit region and a seal ring region surrounding the circuit region, and a dicing lane surrounding the seal ring region, wherein the dicing lane includes a first dicing region and a second dicing region disposed on both sides of the first dicing region;
first active regions formed in the circuit region;
first gate stacks formed on the first active region in the circuit region;
second active regions formed in the first dicing region;
first dielectric gate stacks formed on the second active regions in the first dicing region; and
second dielectric gate stacks formed on an isolation feature in the second dicing region, wherein the first and second dielectric gate stacks are dielectric features, and the first gate stacks are metal gate stacks.

16. The semiconductor structure of claim 15, wherein
the second dicing region is free of active region;
the first and second active regions are longitudinally oriented along a first direction;
the first gate stacks and the first dielectric gate stacks are longitudinally oriented along a second direction being orthogonal to the first direction;
the second dielectric gate stacks are longitudinally oriented along the second direction; and
the second dicing region further includes third dielectric gate stacks longitudinally oriented along the first direction.

17. The semiconductor structure of claim 16, wherein
the second dielectric gate stacks include a first dielectric gate stack, a second dielectric gate stack and a third dielectric gate stack;
the third dielectric gate stacks include a first subset of the third dielectric gate stacks spanning between the first dielectric gate stack and the second dielectric gate stack, and a second subset of the third dielectric gate stacks spanning between the second dielectric gate stack and the third dielectric gate stack; and
the first subset of the third dielectric gate stacks span between the first dielectric gate stack and the second dielectric gate stack.

18. The semiconductor structure of claim 17, wherein the first subset of the third dielectric gate stacks are aligned with the second subset of the third dielectric gate stacks along the first direction.

19. The semiconductor structure of claim 15, wherein
the first active regions include a first width W1;
second active regions include a second width W2; and
the second width is greater than the first width.

20. A method, comprising:
providing a substrate having a circuit region and a seal ring region surrounding the circuit region, and a dicing lane surrounding the seal ring region, wherein the dicing lane includes a first dicing region and a second dicing region disposed on both sides of the first dicing region;
forming first active regions in the circuit region, and second active regions in the first dicing region;
forming first gate stacks on the first active region in the circuit region, first dielectric gate stacks on the second active regions in the first dicing region, and second dielectric gate stacks on an isolation feature in the second dicing region, wherein the first and second dielectric gate stacks are dielectric features, and the first gate stacks are metal gate stacks; and
dicing the substrate along the dicing lane.
